(19) United States
(12) Patent Application Publication
(10) Pub. No.: US 2002/0067297 A1
(43) Pub. Date: Jun. 6, 2002

(54) Pruning calibration flash analog-to-digital converter (ADC) and a method of calibrating and manufacturing the same

(76) Inventors: Conor C. Donovan, Co. Cork (IE); Michael P. Flynn, Co. Cork (IE)

Correspondence Address: Andre L. Marais, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/910,179

(22) Filed: Jul. 19, 2001

Related U.S. Application Data
(60) Provisional application No. 60/219,367, filed on Jul. 19, 2000.

(51) Int. Cl. H03M 1/10

(52) U.S. Cl. 341/120

(57) ABSTRACT

A method to perform a pruning calibration of an analog-to-digital converter (ADC) commences with a pruning operation in relation to a pool of comparators, which includes redundant comparators, of the ADC to select a subset of selected comparators as operational. The selection of the subset of selected comparators may include selecting comparators with trip voltages appropriate to respective codes of an output of the ADC. Each comparator of the subset is assigned to a respective code of the output of the ADC. Unselected comparators within the ADC are operationally powered down. The pool of comparators includes more comparators than are required to product an N-bit output (i.e. the pool includes redundant comparators). The comparators of ADC are not required to be accurate and trip voltages of the pool of comparators are distributed over an input voltage range of the ADC.

### CROSS REFERENCE TO RELATED APPLICATIONS

This application claims the benefit of U.S. Provisional Application No. 60/219,367, filed Jul. 19, 2000.

### FIELD OF THE INVENTION

The present invention relates generally to the field of analog-to-digital converters (ADCs), and in particular to the construction and calibration of a flash ADC.

### BACKGROUND OF THE INVENTION

FIG. 1 is a schematic illustrating a typical prior art flash analog-to-digital converter (ADC) 10 that includes 2ˆ N−1 comparators 12, a resistor ladder 14 including 2ˆ N−1 segments, and an encoder (not shown) coupled to receive the outputs of the comparators 12. The resistor ladder 14 serves to subdivide a reference voltage (V_{f}) 16 into spaced voltages, and accordingly sets trip voltages for each of the comparators 12. Specifically, each comparator 12 ideally has its trip point (or trip voltage) spaced from that of an adjacent comparator by voltage corresponding to one Least Significant Bit (LSB) of the ADC.

The comparators 12 compare an input voltage (Vᵢₙ) 18 to each of the spaced voltages defined by the resistors of the resistor ladder 14, and output a thermometer code, which is converted to a binary code by the encoder. This binary code constitutes the output of the ADC. Specifically, at the encoder, the top of the thermometer code may be detected by a series of two input AND gates. In ideal operation, only a single 1-0 transition will be located. The outputs drive a ROM wordline and the ROM outputs the appropriate digital word. The digital word is directly related to the position of the meniscus (i.e., the top) of the thermometer code.

In practice, errors may arise in the comparator operation where any one of the comparators 12 has a random, and possibly systematic, error. Trip voltage errors may cause the binary code output of the ADC to be inaccurate, and in some circumstances may cause the above-mentioned ROM to malfunction. In order to address the above problem, the comparators 12 of a flash ADC are typically designed to be accurate, or some sort of calibration is used to make each comparator 12 comply accurately with a pre-assigned trip point. Specifically, if the trip point (or trip voltage) of a comparator 12 is more than a LSB from this pre-assigned trip voltage, then the ADC 10 may exhibit significant accuracy errors.

### SUMMARY OF THE INVENTION

A method to perform calibration of an ADC includes performing of a pruning operation in relation to a plurality of comparators of the ADC to select a subset of selected comparators of the plurality of comparators as operational. A subset of unselected comparators of the plurality of comparators is disabled.

The ADC may be a N-bit flash ADC, and the subset of selected comparators may be selected to include 2ˆ N−1 comparators.

The selection of the subset of selected comparators includes selecting each comparator of the plurality of comparators with a perspective trip voltage appropriate to each code of an output of the ADC.

The selection of each of the comparators of the subset of selected comparators includes, for a respective code of the output of the ADC, identifying a code transition voltage for the respective code, identifying the comparator as the comparator of the plurality of comparators with a trip voltage nearest the code transition voltage for the respective code, assigning the identified comparator to a segment of an input voltage range of the ADC, and removing the identified comparator from further consideration for inclusion within the subset of selected comparators.

Other features of the present invention will be apparent from the accompanying drawings and from the detailed description that follows.

### BRIEF DESCRIPTION OF THE DRAWINGS

The present invention is illustrated by way of example and not limitation in the Figures of the accompanying drawings, in which like references indicate similar elements and in which:

FIG. 1 is a schematic illustrating a prior art analog-to-digital converter (ADC).

FIG. 2 is flow chart illustrating a method, according to the exemplary embodiment of the present invention, of calibrating N-bit ADC.

FIG. 3 is a is flow chart illustrating a method, according to the exemplary embodiment of the present invention, of selecting a subset of selected comparators with trip voltages appropriate to each code of the output an ADC.

FIG. 4A is a block diagram illustrating an exemplary ADC in calibration mode.

FIG. 4B is a graph plotting SNDR against redundancy for the nominal number of comparators assigned to code.

FIG. 4C is a block diagram illustrating an alternative exemplary embodiment of an ADC in calibration mode, and illustrates multiple comparator coupled to each other number of reference taps of a resister letter.

FIG. 4D illustrates exemplary ideal and actual comparator searches., with 4D(a) illustrating an ideal comparator search and FIG. 4D(b) illustrating an actual comparator search.

FIG. 4E illustrates the state of comparator as determined during a exemplary comparator search algorithm.

FIGS. 4F and 4G illustrates an exemplary code 2 comparator search.

FIG. 4H is a flow chart illustrating a high-level calibration state diagram, according to the exemplary embodiment of the present invention.

FIG. 4I is a schematic illustrating an exemplary comparator selection system.

FIG. 4J illustrates an exemplary scan flip-flop.

FIG. 4K illustrates an exemplary comparator selection process.

FIG. 4L illustrates multiple valid comparators, in an exemplary use scenario.

FIG. 4M(a) is a graph showing exemplary variations in a signal-to-noise ratio plus distortion ratio (SNDR) of an ADC with DAC resolution.

FIG. 4M(b) illustrates exemplary voltage regions of an input voltage of the ADC that are searched

FIG. 4M(c) is a flow chart showing an exemplary search algorithm.

FIG. 4N illustrates exemplary comparator search state algorithm.

FIG. 4O illustrates an exemplary calibration engine structure, as well as an exemplary state diagram for a CALmc state machine included within the calibration engine.

FIG. 5A is a distribution diagram illustrating a nominal comparator trip voltage distribution, where the nominal trip voltages of the comparators of a pool of comparators within the ADC are uniformly distributed over an input range of the ADC.

FIG. 5B is a distribution diagram illustrating an exemplary actual trip voltages.

FIG. 6A illustrates a nominal comparator trip voltage distribution, where the distribution is extended past the minimum and maximum values of the input voltage range of the ADC.

FIG. 6B is a distribution diagram illustrating an actual comparator trip voltage distribution that may be achieved.

FIG. 7 is a block diagram illustrating an architecture of an encoder included within an ADC, according to an embodiment of the present invention,

FIG. 8 illustrates the division of an exemplary input voltage range into 8 segments in a 6-bit ADC.

FIG. 9 is a block diagram providing further architectural details of an MSB encoder, according to an exemplary embodiment of the present invention.

FIG. 10 is a schematic providing details of the connection of memory cells within the MSB encoder, according to an exemplary embodiment of the present invention.

FIG. 11 provides further examples of words that may be written into rows corresponding to comparator within the SRAM of an MSB encoder, according to an exemplary embodiment of the present invention.

FIG. 12 is a schematic diagram illustrating a residue generator circuit, according to an exemplary embodiment of the present invention, that may be included within an MSB encoder to generate an output residue to an LSB encoder

FIG. 13 is a block diagram illustrating an exemplary machine in the form of a computer system to access a machine-readable medium.

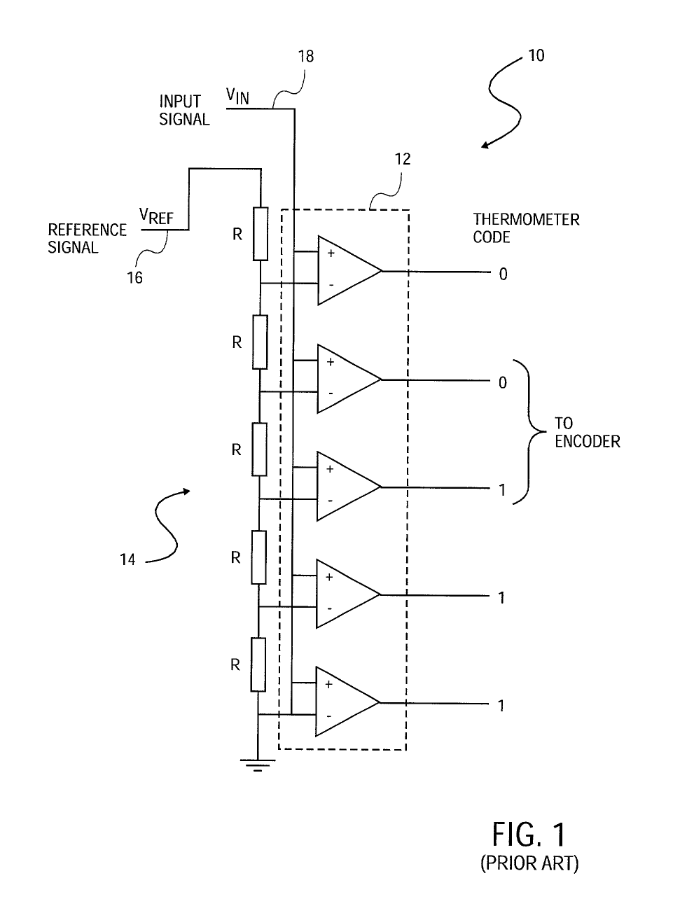

### DETAILED DESCRIPTION

A pruning calibration flash analog-to-digital converter (ADC) and a method of calibrating and manufacturing the same, are described. Ini the following description, for purposes of explanation, numerous specific details are set forth in order to provide a thorough understanding of the present invention. It will be evident, however, to one skilled in the art that the present invention may be practiced without these specific details.

At a high level, the present invention proposes a scheme, according to one aspect of the present invention, that does not require the comparators 12 included within an ADC to be accurate. Specifically, according to one aspect of the present invention, an ADC is manufactured to include substantially more comparators than are traditionally required to produce a N-bit output (i.e., with redundant comparators). Merely for example, a 6-bit ADC utilizing the architecture of the present invention may include 336 comparators, compared to 63 comparators in a prior art flash ADC. The present invention proposes utilizing only a subset of available comparators of an ADC. For example, although 336 comparators may be provided within an ADC, only 63 of these are, in an exemplary embodiment of the present invention, operationally utilized by the flash ADC.

Comparator reassignment is, in one aspect of the present invention, used to provide monotonicity in the presence of offsets.

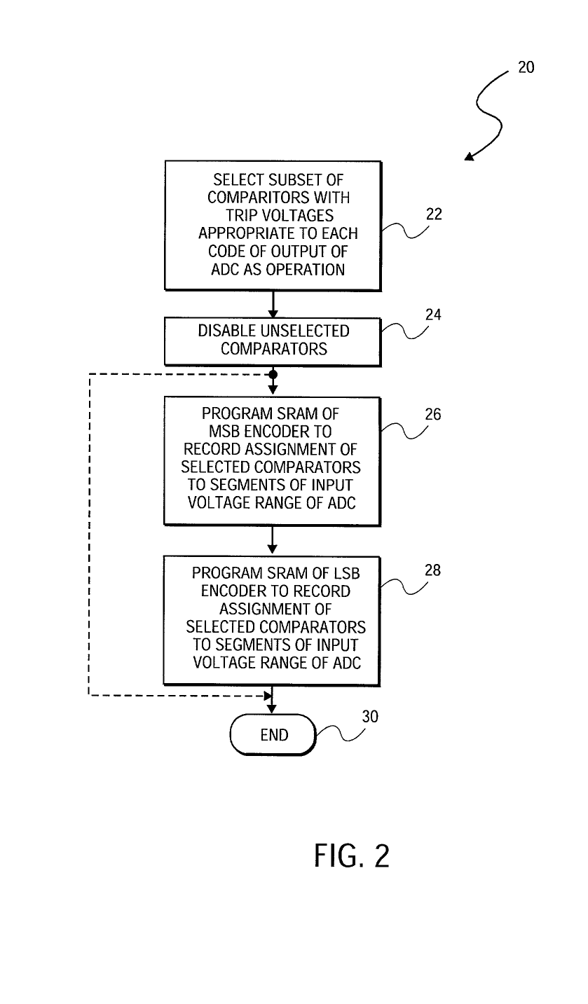

In order to configure an ADC, according to one embodiment of the present invention, for operation, a set up or calibration cycle is implemented. There are a number of components to the calibration cycle. FIG. 2 is a flow chart illustrating at a high level a method 20, according to an exemplary embodiment of the present invention, of calibrating a N-bit flash ADC prior to operation thereof. The method 20 commences at block 22 with the selection of a subset of comparators available in an ADC as operational comparators. Specifically, a comparator with a trip voltage (Vₜᵣᵢₚ) most appropriate to each code of an output of the ADC is assigned to each such code, and in this way selected as being operational. In one embodiment, the subset of selected comparators is selected from a larger pool of comparators that includes at least double the number of comparators required to generate an N-bit output. Indeed, in one specific embodiment, the pool of comparators from which the subset of selected comparators is selected may include at least four times the number of comparators required to generate the N-bit output. In this way, even though comparators included within the pool of comparators may exhibit large nominal trip voltage (Vₜᵣᵢₚ) errors, if the distribution of such trip voltages is uniform over an input voltage range of the ADC, there is a high probability that at least one comparator in the pool will have a trip voltage (Vₜᵣᵢₚ) sufficiently close to the ideal trip voltage (Vₜᵣᵢₚ) of each code. At the conclusion of the operation at block 22, 2ˆ N−1 comparators are selected.

At block 24, the comparators of the pool that remain unselected are disabled. For example, the unselected comparators may be powered down during normal conversion.

Considering, for example a 6-bit ADC, during operations performed at blocks 22 and 24, 63 comparators may be selected from a pool of 336 available comparators for inclusion within a subset of selected comparators. In this example, the pool of 336 comparators thus provide on average, 4 comparators per code plus a number of extra comparators that potentially fall outside a nominal input voltage range of the ADC.

In a prior art flash ADC, a given comparator 12 is associated with a given code. The trip voltages (Vₜᵣᵢₚ) of the comparators are pre-assigned, and the outputs of the comparators 12 can accordingly be hard-wired to ROM inputs. This ROM then converts the array of comparator outputs to a binary code.

Following the performance of the operations at blocks 22 and 24, it will be appreciated that the comparators that would be operationally active, and the trip voltages (Vₜᵣᵢₚ) for such operationally active comparators, will not be known until completion of the operations at blocks 22 and 24. For this reason, outputs of the subset of selected comparators cannot be hard-wired into ROM inputs, as is the case in the prior art. In other words, the relationship between a comparator and an output code will remain unknown until the operations performed at block 22 are complete.

With a view to addressing this issue, a further aspect of the present invention proposes programming an encoder of the ADC to output a N-bit output, based on inputs from at least the subset of selected comparators, in a manner that is not affected by the physical order of the comparators of the subset of selected comparators within the ADC. In one embodiment, this may be achieved by providing an encoder that sums the outputs of the pool of comparators of the ADC to generate a N-bit digital output provided disable comparators each produced an output of a logical 0.

In an alternative embodiment, the encoder may include a programmable memory that is programmed to reflect the selection of the subset of selected comparators as being operationally active. In one exemplary embodiment, the encoder, as will be described in further detail below, includes a Most Significant Bit (MSB) encoder and a Least Significant Bit (LSB) encoder, each of which includes a memory in an exemplary form of a Static Random Access Memory (SRAM) that is programmed to record the assignment of selected comparators of the ADC to segments of the input voltage range of the ADC.

Accordingly, the method 20 as illustrated in FIG. 2, following completion of the operations at blocks 22 and 24, proceeds to block 26, where the SRAM of the MSB encoder is programmed to record assignment of the selected comparators to segments of the input voltage range of the ADC. Similarly, at block 28, the SRAM of the LSB encoder is programmed to record the assignment of selected comparators to segments of the input voltage range of the ADC. Further details regarding the structure and programming of the encoder are provided below.

The method 20 then ends at block 30.

Calibration Cycle

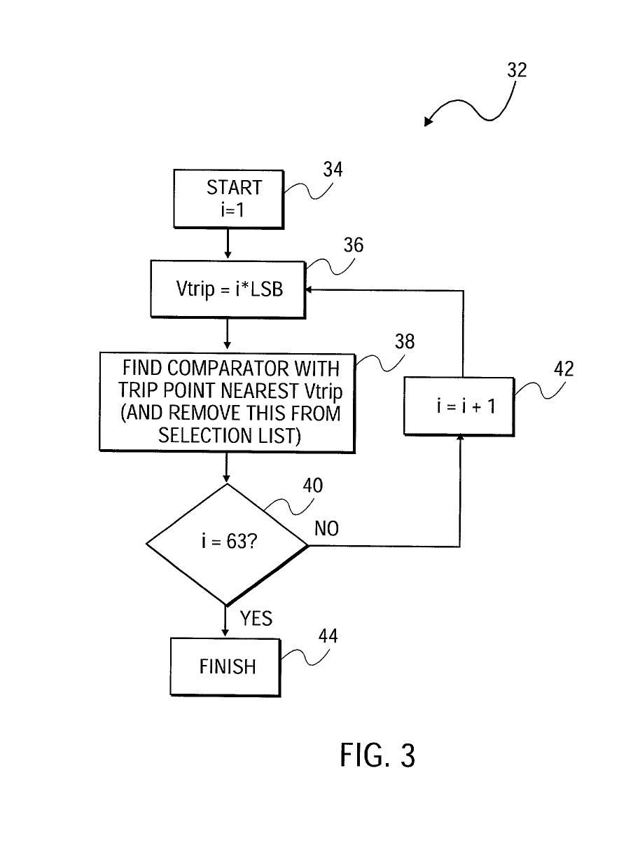

FIG. 3 is a flow chart illustrating a method 32, according to an exemplary embodiment of the present invention, of selecting a subset of selected comparators with trip voltages (Vₜᵣᵢₚ) appropriate to each code of the output of the ADC as operational. As stated above, comparators that are not selected by the method 32 are powered down and, in one embodiment, have a default output of a logical 0. Alternatively stated, one aspect of the present invention includes the introduction of redundant comparators from which a subset is selected as operational. Comparator redundancy produces a high possibility of locating a trip point proximate a specific trip voltage (or code transition point).

The method 32 commences at block 34 with the setting of a loop variable to initial value. At block 36, a first trip voltage (Vₜᵣᵢₚ) is specified as the loop variable multiplied by a Least Significant Bit value of the output code on the ADC.

At block 38, a comparator within the pool of comparators embodied within the ADC having a trip point nearest the trip voltage (Vₜᵣᵢₚ) is located, and assigned (or associated with) a code transition voltage (i.e., a predefined segment of the input voltage range of the ADC). Once assigned, a comparator is furthermore removed from consideration for inclusion within the subset of select comparators. Further details regarding how a comparator is associated with a code transition voltage are provided below.

At block 40, a determination is made as to whether the loop variable has reached a predetermined value (i.e., whether a predetermined number of comparators have been included in the subset of selected comparators based on the number of output bits of the ADC). Following a negative determination at decision block 40, the method 32 proceeds to block 42, where the loop variable is incremented, after which the method 32 then loops back to block 36. On the other hand, following a positive determination at decision block 40, the method 32 terminates at block 44. The assigned comparators have no particular physical order within the ADC, and encoding must accordingly be approached differently than is approached with a typical flash ADC. Two encoding schemed are discussed in further detail below.

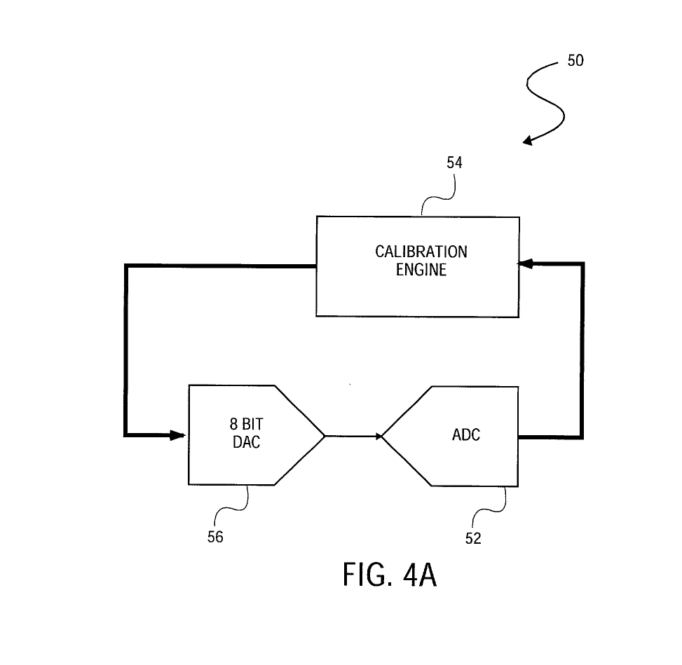

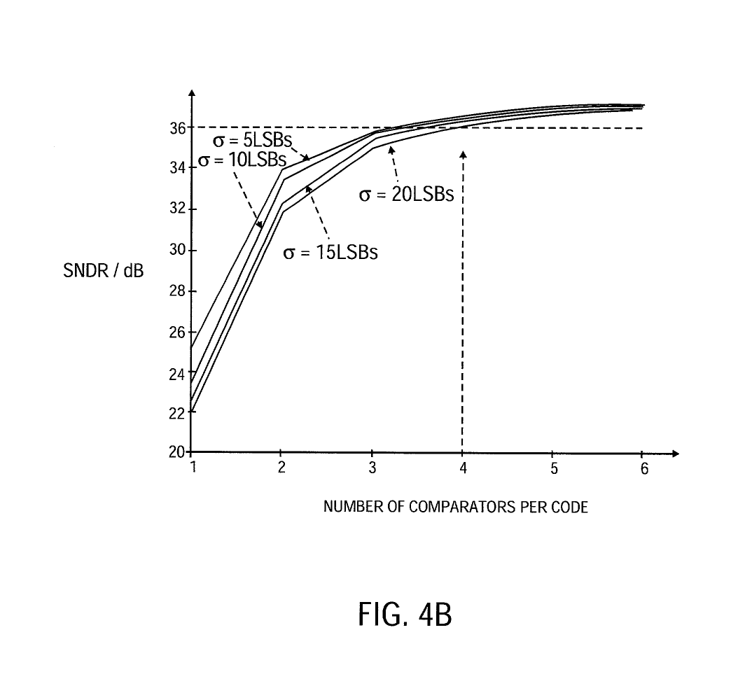

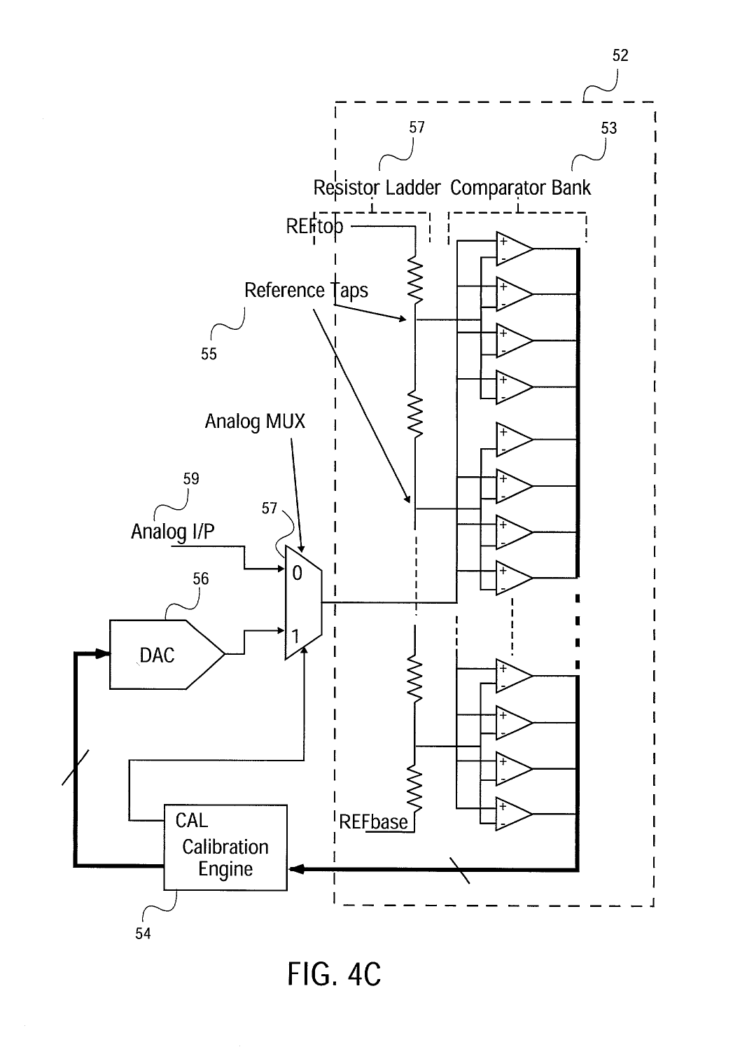

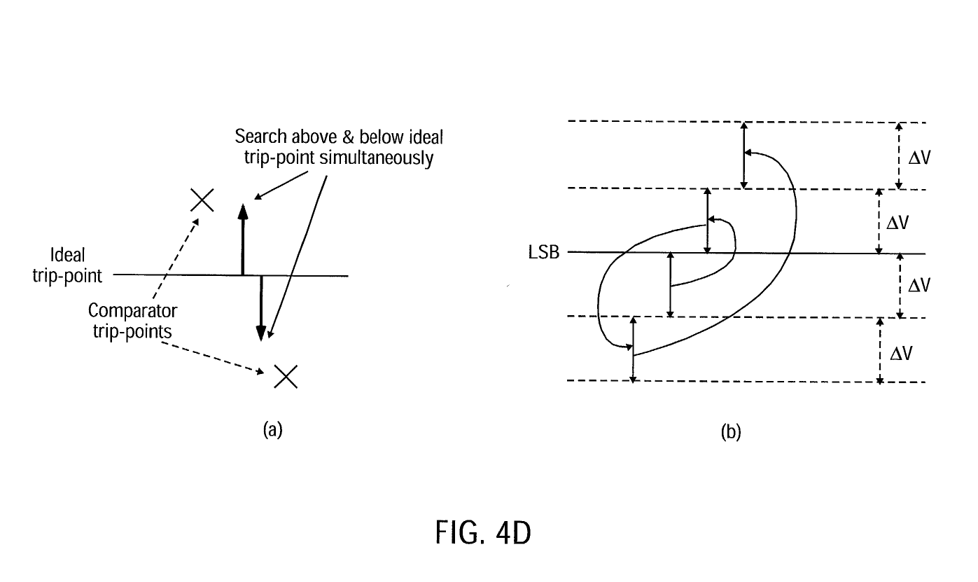

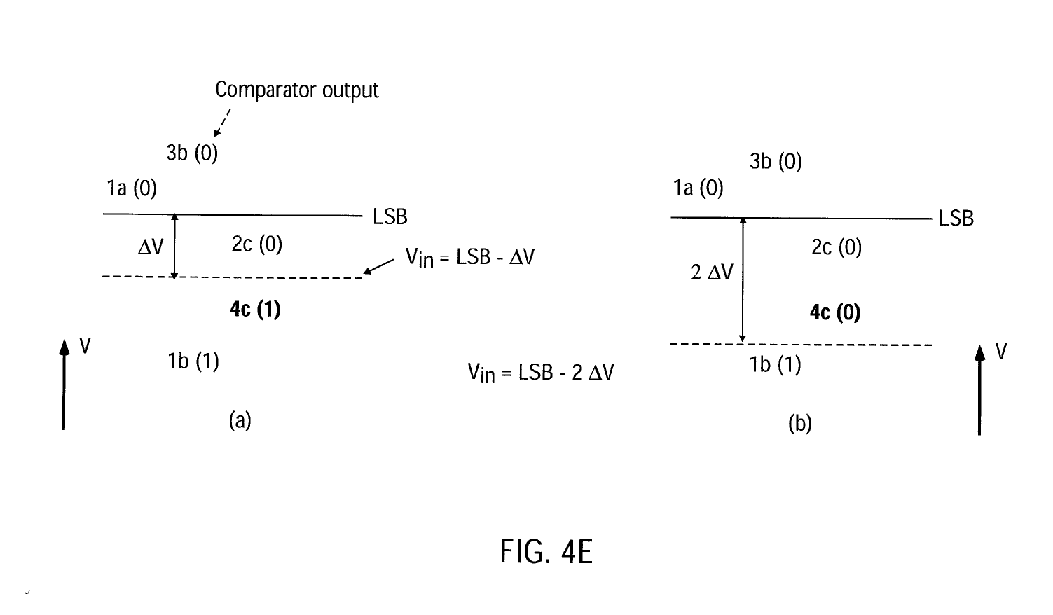

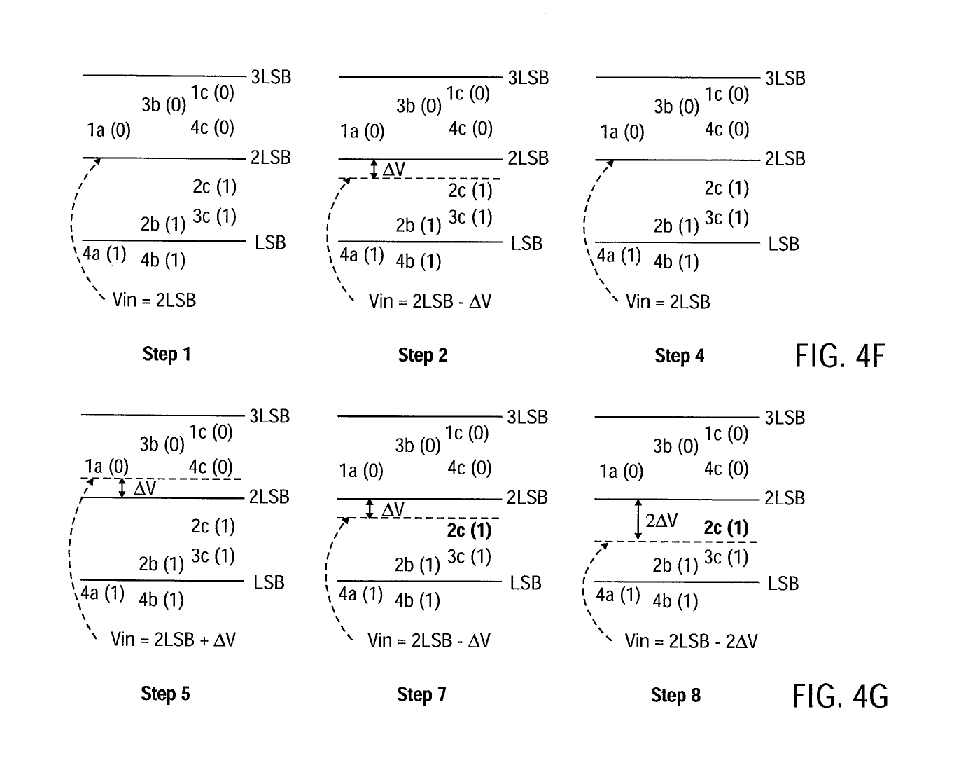

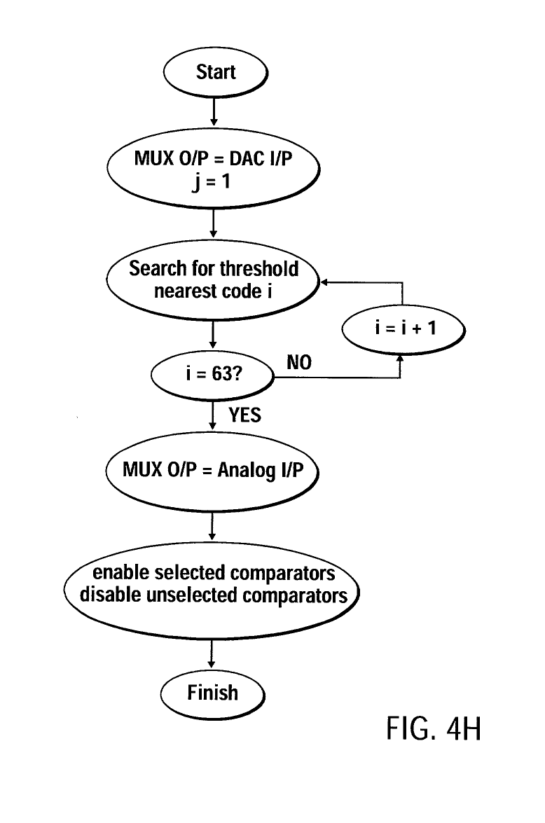

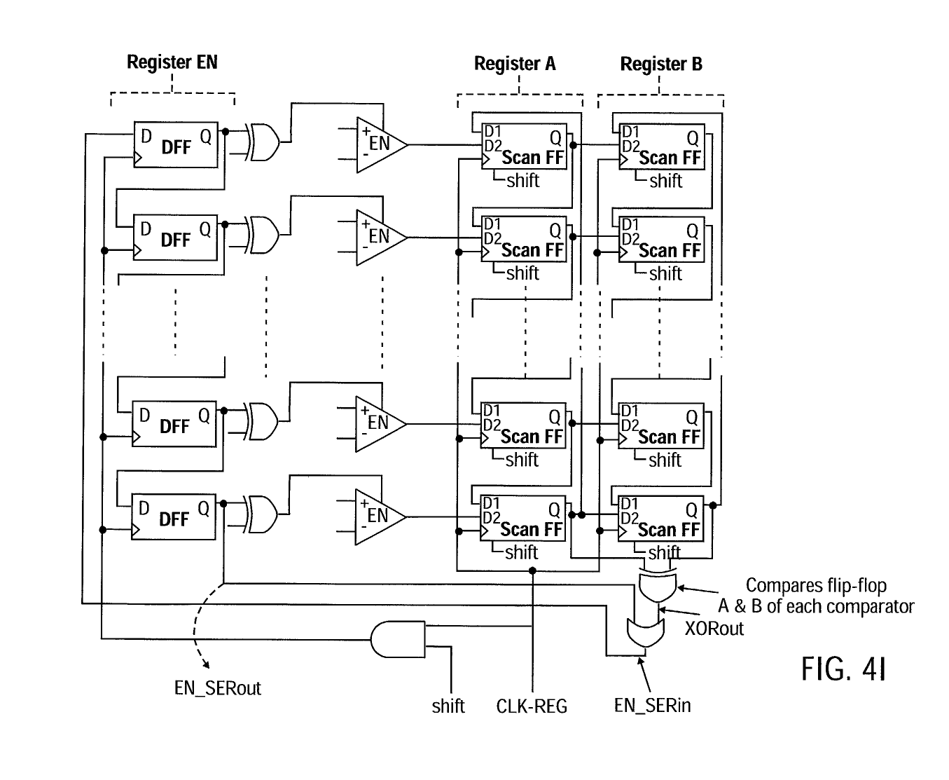

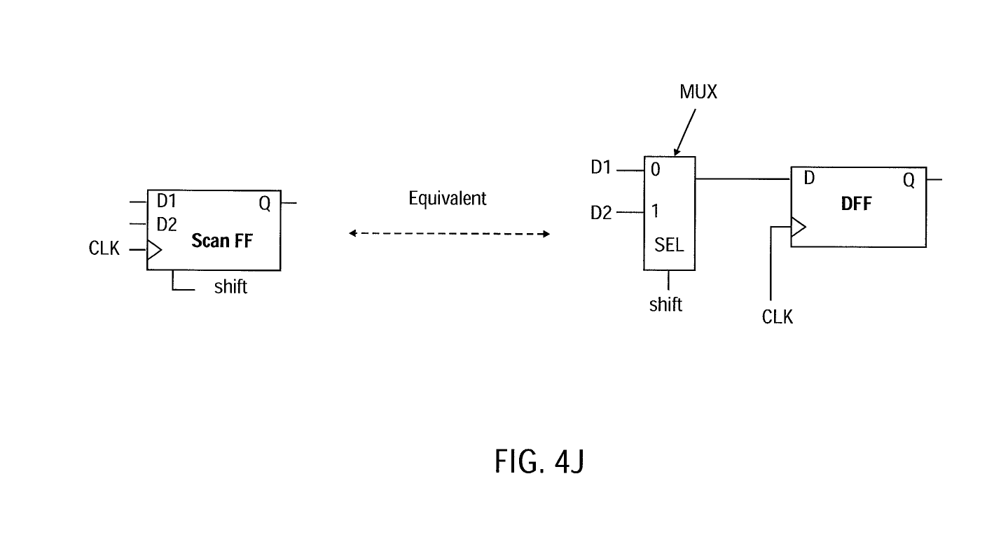

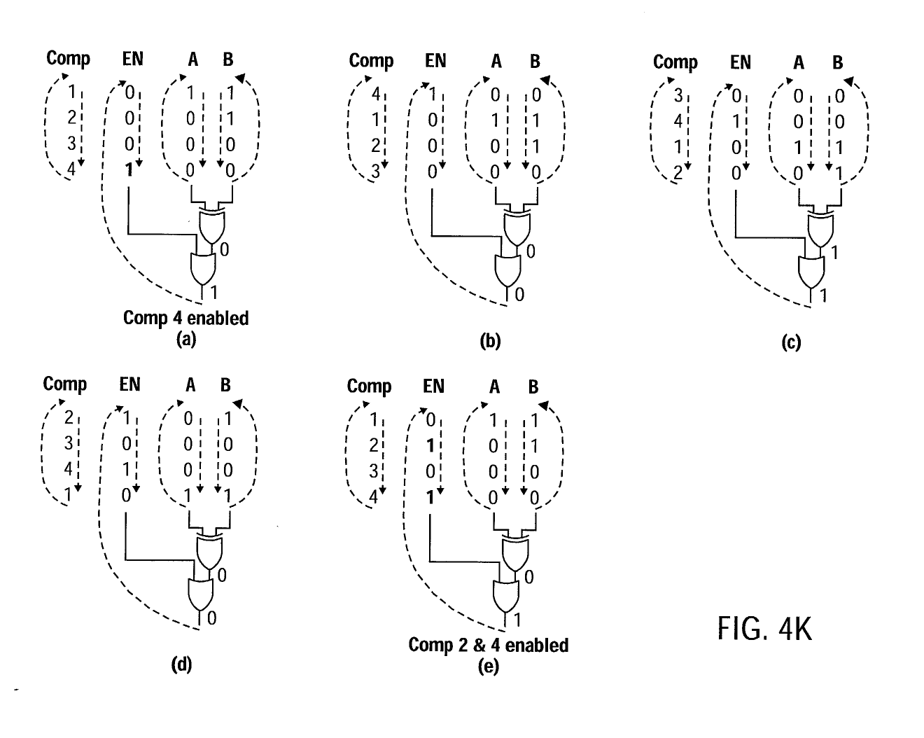

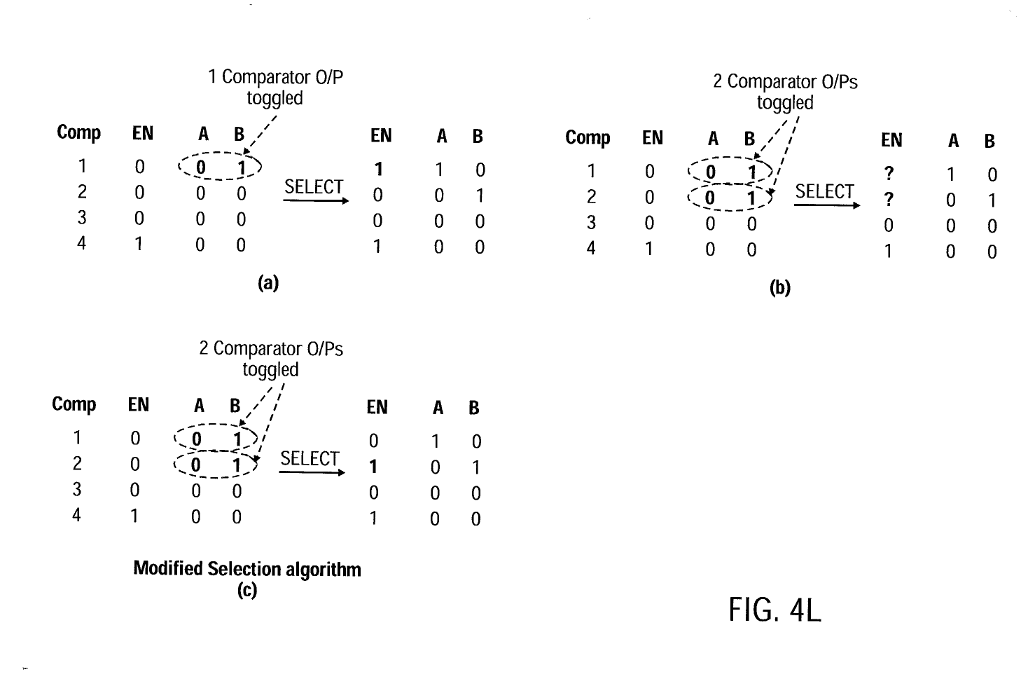

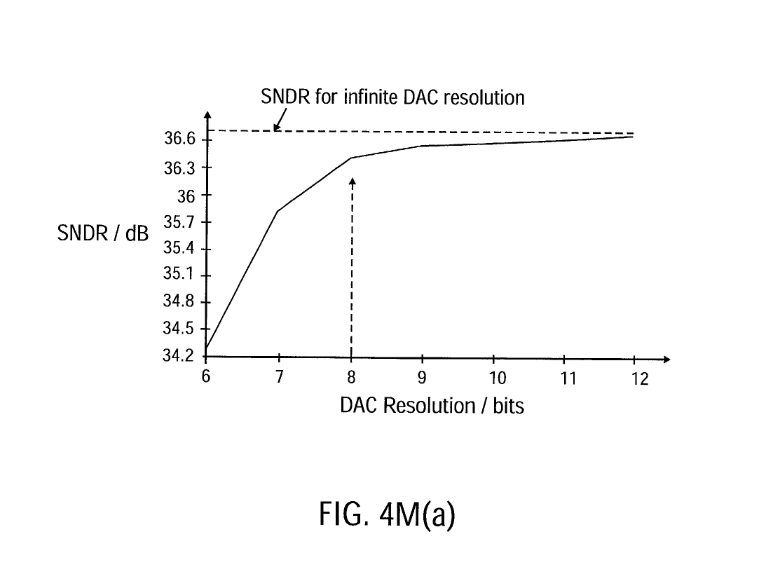

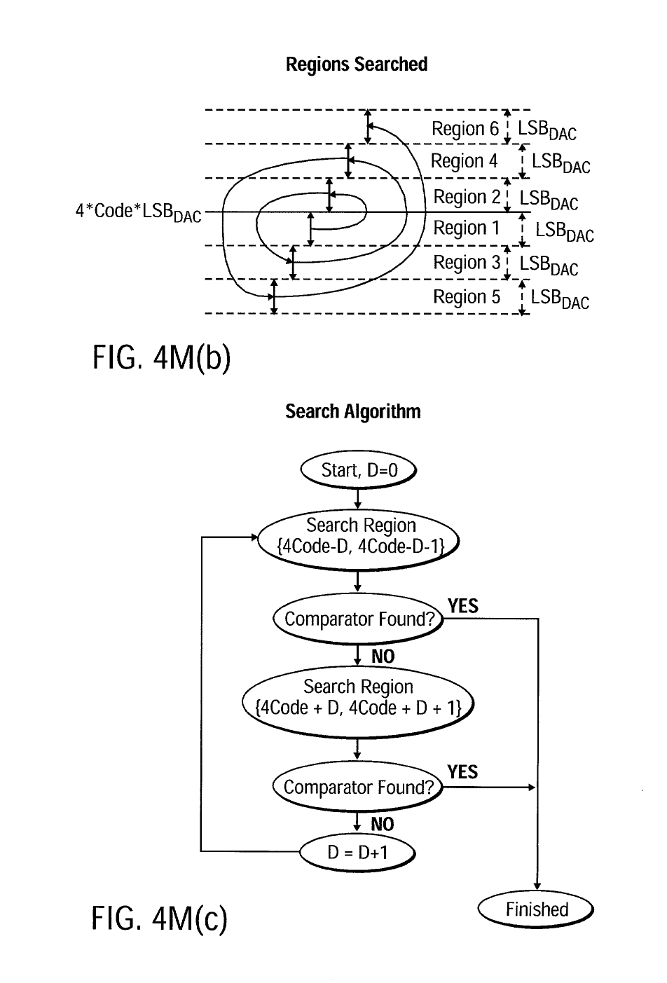

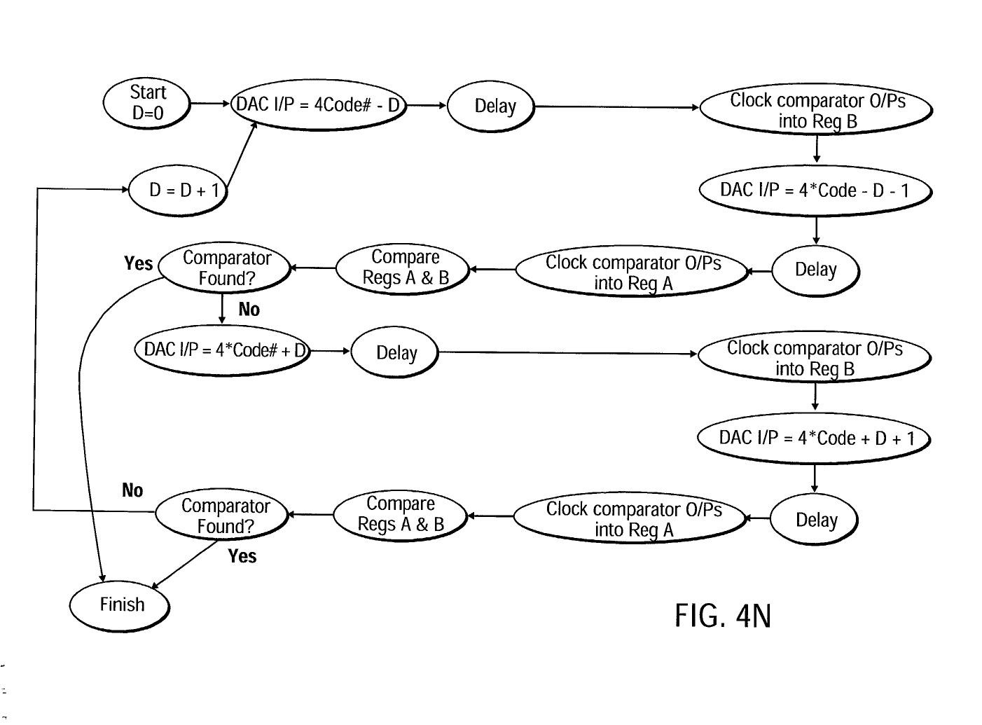

FIG. 4A is a block diagram illustrating an exemplary ADC 50 in calibration mode. Specifically, the calibration operation 32, illustrated in FIG. 3, is controlled by a state machine in the form of a calibration engine 54. A digital-to-analog converter (DAC) 56 is shown to be coupled to the calibration engine 54, and generates an analog input to a bank of comparators 52. During each iteration of the calibration method 32 for a specific ADC code, the input to the bank of comparators 52 from the DAC 56 is swept around a region of an ideal trip point for the relevant ADC code, so as to identify a comparator within the bank of comparators 52 with a trip point nearest the ideal trip point.

For example, considering the calibration of a 6-bit ADC 50, the DAC 56 may have a resolution of 8-bits, this resolution allowing more precision in the assignment of comparators. In practice, the DAC 56 may be implemented utilizing the same resistor ladder as employed in conjunction with the bank of comparators 52. An analog mux connected to the reference ladder selects the appropriate DAC output voltage.

A calibration routine, as may be implemented by the calibration engine 54, is described immediately below in pseudo code:

VIncrement<=fraction of an LSB

for code<=1 to max_code

set DAC voltage to ideal code transition value VIdeal

Compare and latch comparator outputs=<comp_list

repeat

VOffset<=VIncrement

Set VDAC at VIdeal+VOffset

Compare and latch comparator pouts=>comp_list_new

VOffset<=VOffset*−1

if VInc is positive then

VOffset<=VOffset+VIncrement

end

Until comp_list_new is different to comp_list

Of the comparators identified by the difference between comp_list and comp_list_new, assign the one with the higher nominal trip voltage to represent this code.

Remove this comparator from being considered for other codes

end this code

Amount of Redundancy

In order to achieve satisfactory ADC performance, a degree of comparator redundancy should be provided. The redundancy required is related to comparator offset. A simulation has been performed to determine the redundancy necessary for a specific comparator off set.

FIG. 4B illustrates a variation in a signal-to-noise-plus-destortion ratio (SNDR), which was employed as a performance metric used to compare simulation results with redundancy for a various comparator offsets. Utilizing FIG. 4B, the redundancy required to achieve acceptable ADC performance for various comparator offsets may be determined.

In one embodiment, the extra comparators to provide the comparator redundancy are introduced into a comparator bank 53 by coupling to more than one comparator to each of a number of reference taps 55 of a resister ladder 57. To this end, FIG. 4C illustrates an embodiment of the present invention where the ADC 52 includes an arrangement where three comparators are tied to each reference tab 55.

Alternative Methodology-comparator Search

The hardware illustrated in FIG. 4C, in one embodiment of the present invention, may be utilized to perform an alternative comparator search described in the further detail below with Reference to FIGS. 4D-4G.

The principle of the exemplary comparator search is demonstrated in FIG. 4D and outlined below:

1. Search for trip-point in region [(LSB−ΔV)→(LSB)]

2. Search for trip-point in region [(LSB)→(LSB+AV)]

3. Search for trip-point in region [(LSB−ΔV)→(LSB−2ΔV)]

4. Search for trip-point in region [(LSB−ΔV)→(LSB+2ΔV)]

5. . . . etc.

The areas closest to the ideal trip-point are searched initially. As the search progresses, the regions further from the code transition are searched. The routine finished when a comparator is found. To search for a comparator in a particular region e.g. [(LSB−2ΔV)→(LSB+ΔV)]:

1. Apply Vin=(LSB−ΔV) to comparators, record comparator outputs—as in FIG. 4D(a)

2. Apply Vin=(LSB−2ΔV) to comparators, record comparator outputs—as in FIG. 4D(b)

3. If a comparator output has changed, the trip-point lies in this region.

This is demonstrated in FIG. 4E. Note that in changing Vin from (LSB−ΔV) to (LSB−2ΔV) the output of comparator 4c has changed and it can be deduced that the trip-point of comparator 4c lies in this region.

To further demonstrate the comparator search algorithm, consider the trip-point distribution of FIGS. 4F and 4G.

In order to implement the exemplary comparator search described above with reference to FIGS. 4D-4G, the hardware illustrated in FIG. 4C is required. The two primary functions of this hardware are to apply a given DC voltage to the comparators of the comparator bank 53, and to exercise overall execution and control over the search algorithm.

DAC 56 illustrates that in FIG. 4C generates the required analog voltage which forms the comparator input. The resolution of the DAC 56 is determined by the magnitude of ΔV.

An analog mux 57 selects the input to the comparators during calibration and conversion modes. Specifically, during calibration mode, the output of the DAC 56 constitutes the input to the comparator bank 53. In the conversion mode, the analog input 59 constitutes the input to the comparator bank 53.

The calibration engine 54 illustrated in FIG. 4C is a state machine, and executes a high-level state machine, an example of which is illustrated on FIG. 4H. The calibration engine 54 controls overall execution of the comparator search algorithm, the DAC input, and comparison of comparator output (i.e., to comparator output that has changed).

Comparator Selection

In order to detect if a comparator output has changed and assign an appropriate comparator, the calibration engine 54 is capable of:

1. Storing previous and current comparator outputs. Hence 2 flip-flops per comparator is used in one embodiment.

2. Comparing previous and current comparator outputs (to detect if it has toggled).

3. If the comparator output has toggled, assign the comparator.

It is possible to perform steps 2 &3 above serially (one comparator at a time) or in parallel (all comparators simultaneously). The serial solution may require less hardware and is shown in FIG. 4I. Registers A and B store the comparator outputs. The flip-flops in registers A & B are scan flip-flops (see FIG. 4J), hence A & B can be configured as parallel load or shift registers. If the comparator is assigned, the corresponding flip-flop in an EN register is set. The EN register uses D flip-flop and is permanently configured as a shift register. Note that the clock to the EN register is gated by shift, and is clocked when shift=1. To compare flip-flop A and B for each comparator and set the appropriate EN flip-flop:

1. Configure registers A & B as shift registers (i.e., shift=1).

2. Rotate registers A, B & EN fully by clocking them the appropriate amount of times (i.e., if registers are 336 bits wide [symbol] clock 336 times).

If the values stored in A & B differ for a particular comparator, [symbol] XO Rout=1 and the corresponding comparator is assigned. FIG. 4K demonstrates an exemplary procedure for a system with 4 comparators (purely for illustration purposes). FIG. 4K(a) through FIG. 4K(e) show the system as it is stepped from the initial stage through to the final stage. EN-SERin is the serial input to the EN register—if it is high, the corresponding comparator is assigned. EN_SERout is the serial output of the EN register. If it is high, the corresponding comparator has already been assigned.

EN_SERin=1 if and only if:

EN_SERout=1 i.e. comparator already selected or.

Flip-flops A & B of a comparator differ [symbol] comparator should be selected.

FIG. 4K shows an example of the comparator selection process, in this case, a system with 4 comparators has been clarity. A and B show the comparator outputs, while EN shows the assigned comparators. FIG. 4K(a) shows the initial state of the registers before the comparator search begins. As the registers are shifted once, the new state of the registers is given in FIG. 4K(b). FIG. 4K(c) denotes the next state, etc. Note in the initial & final states of the comparator search:

Initial State—FIG. 4K(a)

Comparator 4 has already been selected—EN bit has been set and should not be reset.

Comparator 2 outputs in A & B differ=>Comparator 2 should be selected.

Final State—FIG. 4K(e)

Comparator 4 still remains selected

Comparator 2 has been selected.

FIG. 4K details an exemplary comparator selection process for the situation where the output of only one comparator has toggled. However the scenario can arise whereby the outputs of 2 comparators have toggled, as shown in FIG. 4L(b). Both of the comparators 1 and 2 are valid comparators, however only one comparator can be chosen. It is an arbitrary decision which comparator is selected, since it is difficult to determine which comparator is closest to the code transition point. In the comparator selection algorithm, the bottommost valid comparator is selected. Hence in the above example, comparator 2 is selected and comparator 1 is ignored (FIG. 4K). This function required a minimal change to the EXOR/OR gate combination of FIG. 4K, which generates the serial input to the EN register.

DAC Control

The DAC 54 shown in FIG. 4C is utilized in the exemplary implementation of the calibration algorithm. The resolution determines the size of the ΔV used in the search for a comparator. Sufficient resolution is necessary to allow the accuracy of the comparator search to approach that of an ideal comparator search (i.e., infinite DAC precision or infinitely small Δ). FIG. 4M shows exemplary variations in a signal-to-noise ratio plus distortion (SNDR) of the ADC with DAC resolution.

SNDR tends asymptotically towards the ideal SNDR as the DAC resolution increases. However increased DAC resolution increases the DAC complexity. Taking this into consideration, a DAC resolution of 8-bits may be sufficient, in an exemplary embodiment. The DAC output voltage range may be identical to the ADC input voltage range. Since the DAC is 8-bit resolution and the ADC is 6-bit resolution [symbol] 4LSB_{DAC}=LSB_{DAC}. An exemplary algorithm and diagram indicating regions searched during a comparator search is detailed in FIG. 4N. The procedure for searching region 1 is:

1. DAC input=4* Code, clock comparator outputs into flip-flops.

2. DAC input=4* Code−1, clock comparator outputs into flip-flops.

3. Compare registers A and B, if different, a valid comparator found.

Incorporating this procedure into the state diagram in FIG. 4M yields an exemplary state diagram of the comparator search method, as shown in FIG. 4N. After every change in the DAC input, a delay is included. This allows sufficient settling time for the DAC output. A DAC with a long settling time may be easier to design and may occupy less area than one with a short settling time.

Calibration Engine Structure

The calibration engine 54 controls the DAC 56 and the clocking of registers A, B and EN described above. It also controls overall execution of the calibration sequence. It is a state machine and implements the state diagram given in FIG. 4N for each of the 63, codes in the exemplary scenario. The calibration engine is in one embodiment divided into 2 state machines—CALmc and Comp-Search as shown in FIG. 4O.

The state machine Comp-Search executes a comparator search as illustrated in FIG. 4N. Given a particular code, Comp-Search finds the most suitable comparator for that code. CALmc determines the code for which Comp-Search is to conduct a comparator search. The functionality of CALmc is described in the state diagram shown FIG. 4O(b). Both CALmc and Comp-Search may be coded using Verilog.

Distribution of Comparator Trip Voltages

It will be appreciated that, in order to facilitate selection of a comparator with a trip voltage appropriate to each code at block 22 of the method 20 shown in FIG. 2, a distribution of the trip voltages across the input voltage range of the ADC is favorable. Specifically, for each code there should ideally be a comparator within the pool of comparators with an actual trip voltage that is close in value to a voltage represented by the respective code. It will be noted that the trip points of the comparators are not required to be accurate; preferably the pool of comparators includes a comparator having an actual trip point close to a code transition voltage.

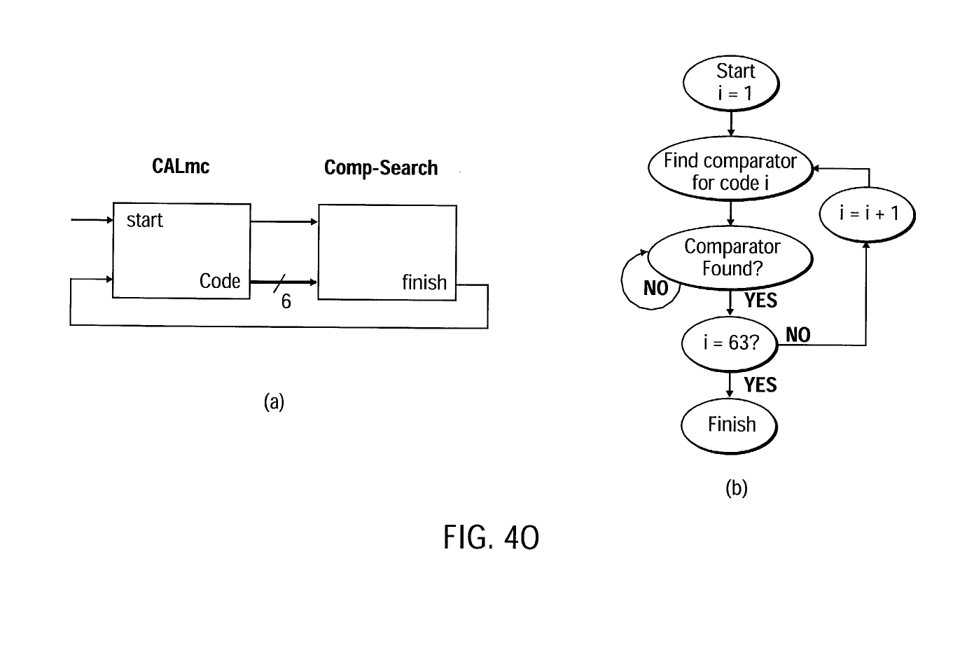

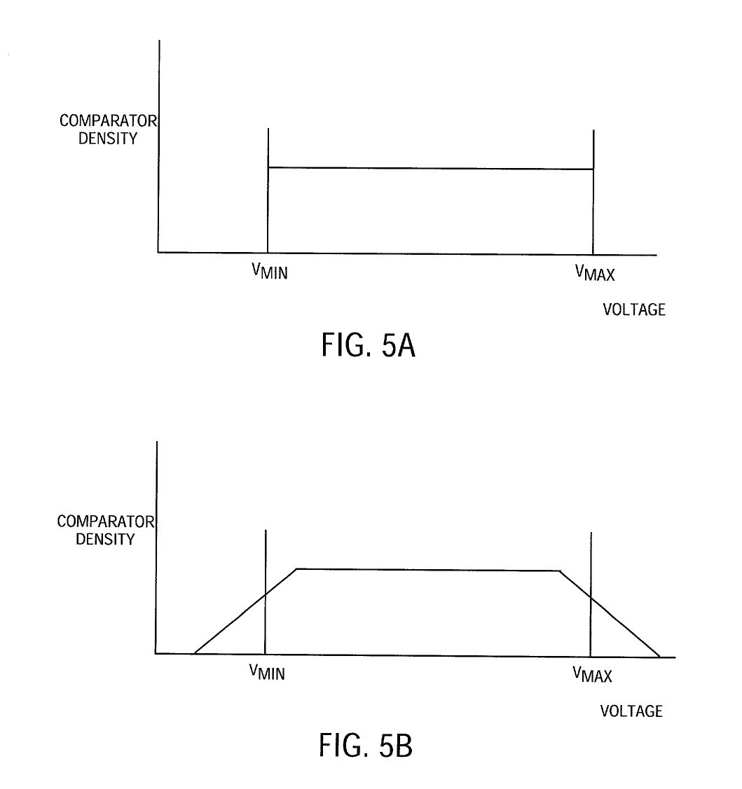

FIG. 5A illustrates a nominal comparator trip voltage distribution, where the nominal trip voltages of comparators of the pool of comparators within the ADC are uniformly distributed over an input range of the ADC (i.e., between Vₘᵢₙ and Vₘₐₓ). If the actual trip voltages exhibit a large variance, the actual comparator trip voltage distribution is most likely better reflected by FIG. 5B. Specifically, FIG. 5B illustrates that the comparator trip voltages may be defused past the extremes of the input voltage range of the ADC. This gives rise to the potential problem that the pool of comparators available within the ADC does not include a sufficient number of comparators with trip voltages near the extremes (or ends) of the input voltage range of the ADC to enable useful comparators to be assigned to codes in these regions.

In order to address this potential problem, the present invention proposes three alternative solutions. Firstly, the nominal trip point density of the comparators may be increased over the entire input voltage range of the ADC, so that there is a sufficient density of trip point across the entire input voltage range (from minimum to maximum values) of the ADC (e.g., so that the distribution extends beyond the minimum and maximum values of the input voltage range). Secondly, the comparator density can be increased close to the extremes of the input voltage range of the ADC, so that there is a increase number of actual trip points approximate the maximum and minimum values of the input voltage range of the ADC.

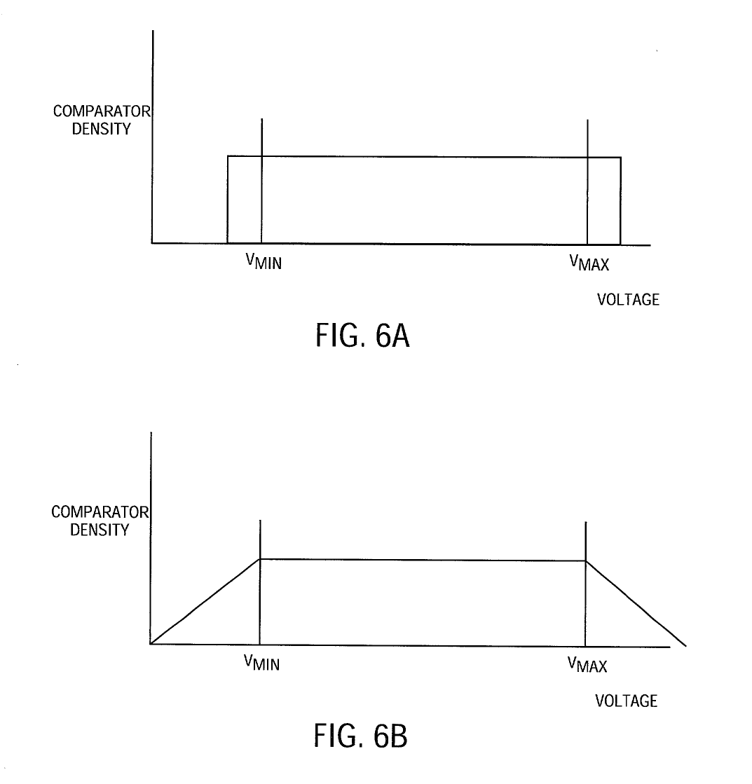

Thirdly, the nominal comparator distribution may be extended past the extremes of the input voltage range of the ADC, to insure that the actual comparator distribution will be uniform throughout the input voltage range. To this end, FIG. 6A illustrates a nominal comparator trip voltage distribution, where the distribution is extended past the minimum and maximum values of the input voltage range of the ADC. FIG. 6B provides an actual comparator trip voltage distribution that may be achieved.

For example, in the case of a 6-bit flash ADC, four comparators may be assigned to each code. The remainder of 336 comparators included within the pool of comparators are then utilized to extend the nominal comparator trip voltage distribution past the nominal input voltage range of the ADC, as illustrated in FIG. 6A.

Encoder

As described above with reference to FIG. 2, the actual trip points of the comparators of the ADC 50 will not be known until the conclusion of the operations performed at block 22 of FIG. 2. For this reason, the comparator outputs cannot be hard-wired into ROM inputs, and the relationship between a comparator and an output code of the ADC will not be known until the operations performed at block 22 are complete. Accordingly, an encoder scheme to accommodate the dynamic selection of the subset of selected comparators from the comparator pool of the ADC 50 is required.

The traditional manner of producing a digital code from an array of comparator outputs includes locating the meniscus of the thermometer code outputted thereby, and encoding this meniscus (or top value) as a binary code.

According to the present invention, an alternative manner of producing a digital code comprises counting the number of 1's outputted from all comparators included within the pool of comparators. It will be appreciated that 1's will only be generated by comparators included within the subset of selected comparators for which the input voltage exceeds the respective trip voltages. In this exemplary embodiment, the comparator outputs of all comparators are summed to provide a digital output code. Specifically, as unselected comparators of the pool of comparators will have a default logical zero (0) output, if all the comparator outputs are summed, a correct digital output value will result since the unselected comparator outputs are ignored. This embodiment operates with the ADC scheme, according to the present invention, as the method is not affected by the physical order of comparators within the ADC.

A disadvantage of this method is that it may be slow and require several stages of pipelining, specifically where the pool of comparators is large. Pipelining may result in the introduction of several latency clock cycles. For example, in the 6-bit ADC example discussed above, the outputs of 336 comparators will be required to be summed to generate the digital output code. Nonetheless, while not providing performance optimization, this methodology is attractive in that it is relatively easy to design, and does not require any programming of the ADC during calibration.

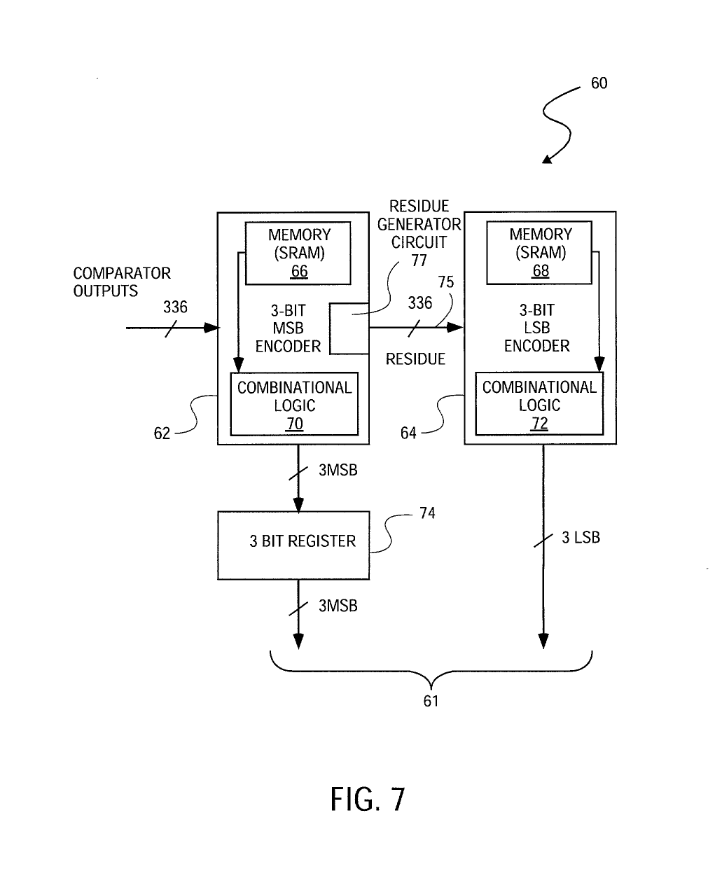

FIG. 7 is a block diagram illustrating the architecture of an encoder 60, according to an alternative embodiment of the present invention. For the purposes of illustration, the encoder 60 is described as being employed within a 6-bit ADC 50, which provides a pool of 336 comparators. It will of course be appreciated that the pool of comparators may include a different number of comparators, or that an alternative scheme may be utilized for an ADC with a different resolution.

In FIG. 7, the encoder 60 is shown to receive inputs from both selected and unselected comparators of the ADC (e.g., all 336 comparators), and to output a 6-bit digital word. The encoder 60 differs from the summing embodiment discussed above in that the encoder 60 is programmed during the calibration method 20, as discussed above with reference to FIG. 2. In one embodiment, the encoder 60 operates to perform encoding in two clock cycles.

The encoder 60 is shown to include a 3-bit Most Significant Bit (MSB) encoder 62 and a 3-bit Least Significant Bit (LSB) encoder 64. The MSB encoder 62 operates to receive all outputs of the pool of comparators, to determine the three most significant bits, and output a “residue” 75 (as described in further detail below) to the LSB encoder 64. The LSB encoder 64, in turn, receives the “residue” 75 as input from the MSB encoder 62, and determines the three least significant bits of the 6-bit digital word 61.

The MSB encoder 62 is furthermore shown to output the three most significant bits to a 3-bit register 74, which is utilized to synchronize the outputs of the most and least significant bits as a 6-bit digital word.

The MSB encoder 62 and the LSB encoder 64 include respective memories, in the exemplary form of Static Random Access Memories (SRAMs) 66 and 68 and combinational logics 70 and 72 that operate on the output of the SRAMs 66 and 68 to generate the most significant bit and least significant bit outputs respectively.

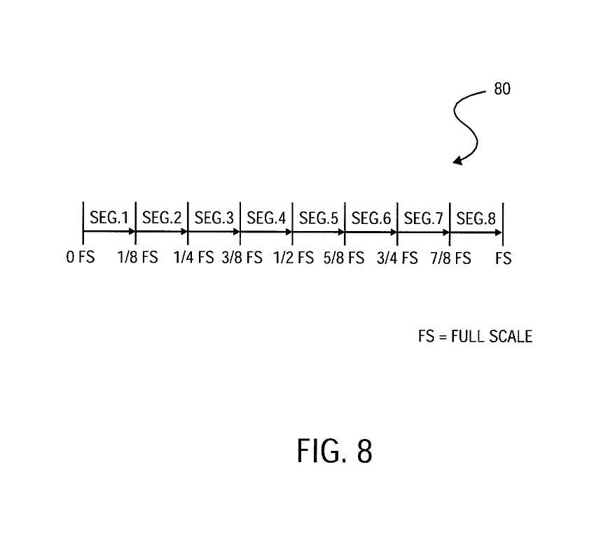

Dealing now more specifically with the MSB encoder 62. As discussed above, this encoder 62 receives as input the outputs from the pool of comparators and determines the 3 most significant bits of 6-bit digital word 61. Specifically, in the exemplary embodiment, the MSB encoder 62 determines in which segment of an input voltage range an input voltage (Vᵢₙ) 18 lies. FIG. 8 illustrates the division of an exemplary input voltage range 18 into 8 segments in a 6-bit ADC.

The MSB encoder 62 includes a memory in the exemplary form of a SRAM 66. In one embodiment, the SRAM 66 includes a row of memory cells dedicated to each of the comparator inputs. In the exemplary embodiment, the SRAM 66 of the MSB encoder 62 may thus comprise 336 words (i.e., a 7-bit wide word for each comparator input). The output word of the SRAM 66 forms a thermometer code, the position of the meniscus (i.e., the top) of the thermometer code indicating the segment in which the input voltage (Vin) lies. Table 1 below provides the relationship between the segments illustrated in FIG. 8, and the MSB thermometer code, according to the exemplary embodiment:

TABLE 1
Thermometer codes for input voltage segments

| MSB | | | | | | | | |
|---|---|---|---|---|---|---|---|---|
| thermometer | Seg. | Seg. | Seg. | Seg. | Seg. | Seg. | Seg. | Seg. |
| code | 1 | 2 | 3 | 4 | 5 | 6 | 7 | 8 |
| Bit 7 | 0 | 0 | 0 | 0 | 0 | 0 | 0 | 1 |
| Bit 6 | 0 | 0 | 0 | 0 | 0 | 0 | 1 | 1 |
| Bit 5 | 0 | 0 | 0 | 0 | 0 | 1 | 1 | 1 |
| Bit 4 | 0 | 0 | 0 | 0 | 1 | 1 | 1 | 1 |
| Bit 3 | 0 | 0 | 0 | 1 | 1 | 1 | 1 | 1 |
| Bit 2 | 0 | 0 | 1 | 1 | 1 | 1 | 1 | 1 |
| Bit 1 | 0 | 1 | 1 | 1 | 1 | 1 | 1 | 1 |

The 7-bit MSB thermometer code outputted from the SRAM 66 is then encoded by the combination logic 70 of the MSB encoder 62 to provide the binary three most significant bits of the 6-bit digital word output of the ADC.

During the calibration method 20, as illustrated at block 26, the SRAM 66 is programmed to record the assignment of selected comparators to segments of the input voltage range of the ADC. As described above, the SRAM 66 includes a number of rows, each row being dedicated to a specific comparator within the pool of comparators of the ADC. In one embodiment, each row of the SRAM 66 has a word written to it during the operation performed at block 26 of FIG. 2. The word written to the appropriate row of memory cells within the SRAM 66 depends whether or not the corresponding comparator is selected during the operation performed at block 22. If the comparator is selected, the word written to the corresponding row of memory cells within the SRAM 66 depends on the segment of the input voltage range in which the trip voltage of the relevant comparator lies. Words written to the various rows of the SRAM 66, according to the exemplary embodiment of the present invention, are provided below in Table 2:

TABLE 2
Row words for input voltage segments

| Segment | Bit 7 | Bit 6 | Bit 5 | Bit 4 | Bit 3 | Bit 2 | Bit 1 |
|---|---|---|---|---|---|---|---|
| UnSelected | 0 | 0 | 0 | 0 | 0 | 0 | 0 |
| 1 | 0 | 0 | 0 | 0 | 0 | 0 | 0 |
| 2 | 0 | 0 | 0 | 0 | 0 | 0 | 1 |
| 3 | 0 | 0 | 0 | 0 | 0 | 1 | 0 |
| 4 | 0 | 0 | 0 | 0 | 1 | 0 | 0 |
| 5 | 0 | 0 | 0 | 1 | 0 | 0 | 0 |
| 6 | 0 | 0 | 1 | 0 | 0 | 0 | 0 |
| 7 | 0 | 1 | 0 | 0 | 0 | 0 | 0 |
| 8 | 1 | 0 | 0 | 0 | 0 | 0 | 0 |

To summarize, each comparator of the pool of comparators within the ADC has a corresponding row of memory cells in the SRAM 66 of the MSB encoder 62. Data (e.g. a Q-bit word) that is written to the row of memory cells is determined by whether the corresponding comparator is selected and, if so, by the segment of the input voltage in which the trip point of the respective comparator lies. If a comparator is selected, and having determined in which segment the trip point of the comparator lies within, the word to be written to the SRAM 66 in the exemplary embodiment of the invention may be found by examining Table 2. On the other hand, if a particular comparator is unselected, zeros are written to the appropriate row of memory cells within the SRAM 66.

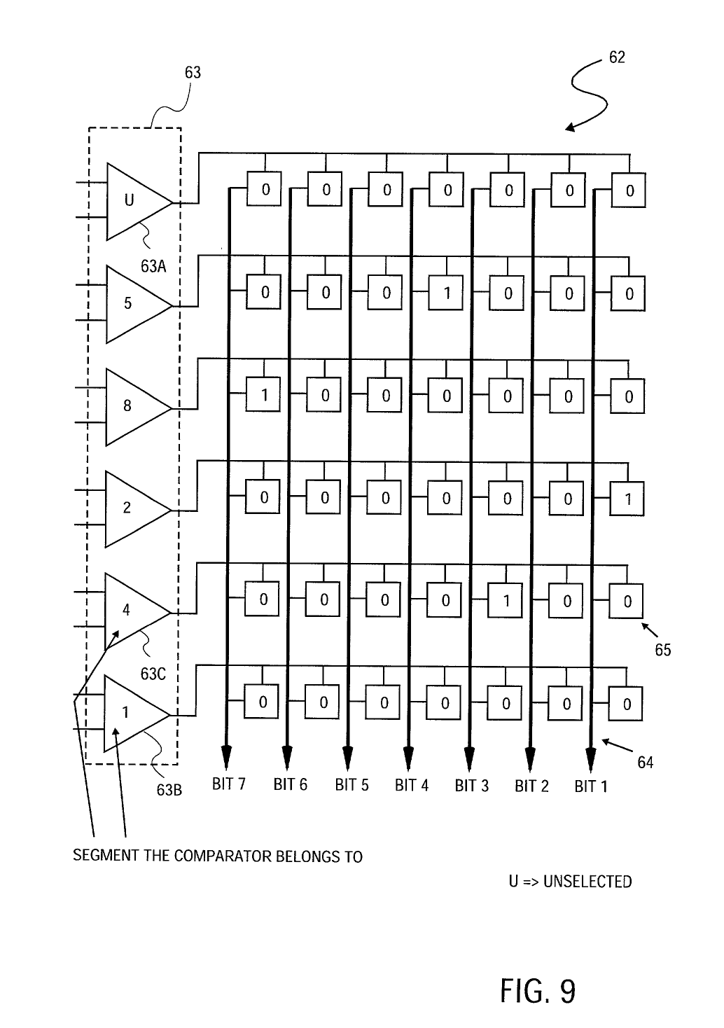

FIG. 9 is a block diagram providing further architectural details of the MSB encoder 62, according to an exemplary embodiment of the present embodiment of the present invention. The contents of the memory locations are ANDed with the outputs of the comparators 63 at each cell. The results of this operation are ORed together to generate output bits 1-7. In effect, these operations cause the state of SRAM 66 to be accessed. FIG. 9 illustrates only a section of the MSB encoder 62, and shows how each memory cell of the SRAM 66 is utilized to determine if a respective comparator 63 is coupled to a specific bit line 67 that provides input to the combinational logic 70. The segment of the input voltage range of the ADC in which each comparator 63 lies is also illustrated within the body of each of the shown comparators 63. The contents of the memory cells 65 of the SRAM are set during the calibration operation at block 26, as described above with reference to FIG. 2.

In the exemplary MSB encoder 62 illustrated in FIG. 9, a trip voltage of a top comparator 63ₐ is found during a calibration cycle not to lie in any of the 8 segments of the input voltage range. Accordingly, all memory cells in the row of the SRAM 66 associated with this comparator 63ₐ are set to “0”. In other words, the comparator 63ₐ does not affect the MSB word outputted from the SRAM 66.

On the other hand, the trip voltage of a bottom comparator 63_{b}, illustrated in FIG. 9, is found during the calibration cycle to lie in segment 1 of the input voltage range of the ADC. Accordingly, this comparator should generate a 3-bit MSB of “0”. Accordingly, all memory cells in the row associated with the comparator 63_{b} are again set to “0”.

The trip voltage of a comparator 63_{c}, the second comparator from the bottom in FIG. 9, is found during calibration to lie in segment 4 of the input voltage range. Accordingly, the memory cells associated with an MSB value of 3 within the row of memory cells of the SRAM 66 associated with the comparator 63_{c} are programmed to be “1”, as illustrated in FIG. 9.

Each bit line 67 outputted from the SRAM 66 may be viewed as acting as a distributed NOR gate, each of which has 336 inputs in the exemplary embodiment. When the output of a particular comparator 63 is high, the bits in the corresponding row of memory cells within the SRAM 66 are passed to the NOR gate inputs. Alternatively, if the output of the relative comparator 63 is low, input of the NOR gate must be low. If a logical 0 is written to a memory cell, the input to the NOR gate must be low regardless of the state of the comparator output.

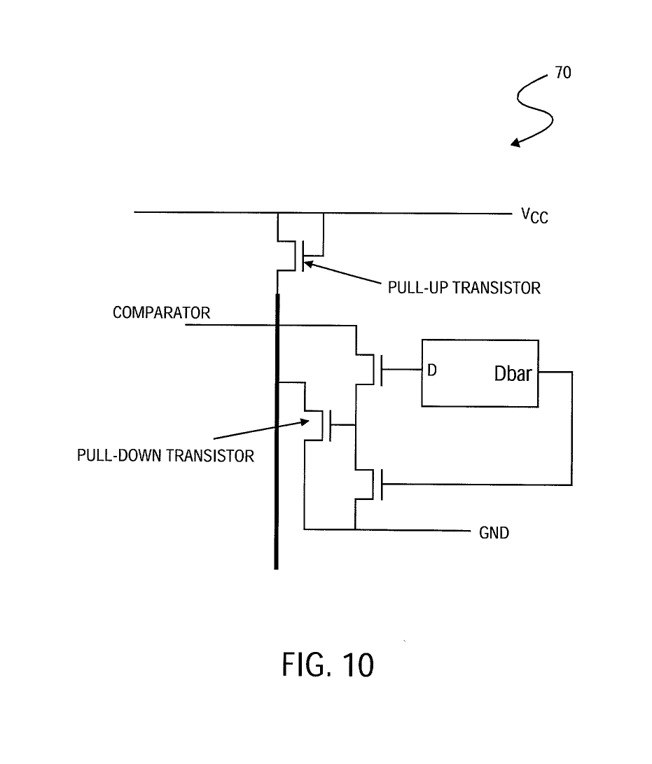

FIG. 10 is a schematic providing details of the connection of a memory cell 65 to a bit line 67, according to an exemplary embodiment of the present invention.

Turning now to the LSB encoder 64, this encoder 64 is similar to the MSB encoder 62 in architecture. The LSB encoder 64, however, differs from the MSB encoder 62 with respect to the codes written to the rows of memory cells. Specifically, a word written to a row of memory cells within the LSB encoder 64, and associated with a comparator of the comparator pool, is related to the LSBs of the code associated with the particular comparator. As with the MSB encoder 62, the content of the memory cells is decided and programmed during the calibration method 20, and specifically during operations performed at block 28 illustrated in FIG. 2. The output of the SRAM 68 of the LSB encoder 64, as with the output of the SRAM 66 of the MSB encoder 62, forms a thermometer code. Table 3, below, provides the thermometer code for LSB outputs of the SRAM 68, according to the exemplary embodiment of the present invention:

TABLE 3
Row words for LSBs

| 3LSBs | 000 | 001 | 010 | 011 | 100 | 101 | 110 | 111 |
|---|---|---|---|---|---|---|---|---|
| Bit 7 | 0 | 0 | 0 | 0 | 0 | 0 | 0 | 1 |
| Bit 6 | 0 | 0 | 0 | 0 | 0 | 0 | 1 | 1 |
| Bit 5 | 0 | 0 | 0 | 0 | 0 | 1 | 1 | 1 |
| Bit 4 | 0 | 0 | 0 | 0 | 1 | 1 | 1 | 1 |
| Bit 3 | 0 | 0 | 0 | 1 | 1 | 1 | 1 | 1 |
| Bit 2 | 0 | 0 | 1 | 1 | 1 | 1 | 1 | 1 |
| Bit 1 | 0 | 1 | 1 | 1 | 1 | 1 | 1 | 1 |

From the above table, for example, if a comparator is selected with a trip point of 23*LSB, the corresponding binary code is “0 1 0 1 1 1”. The three LSB's of this code are “1 1 1” and accordingly referencing Table 3, the word written into the appropriate row of memory cells within the SRAM 68 is “1 1 1 1 1 1 1”.

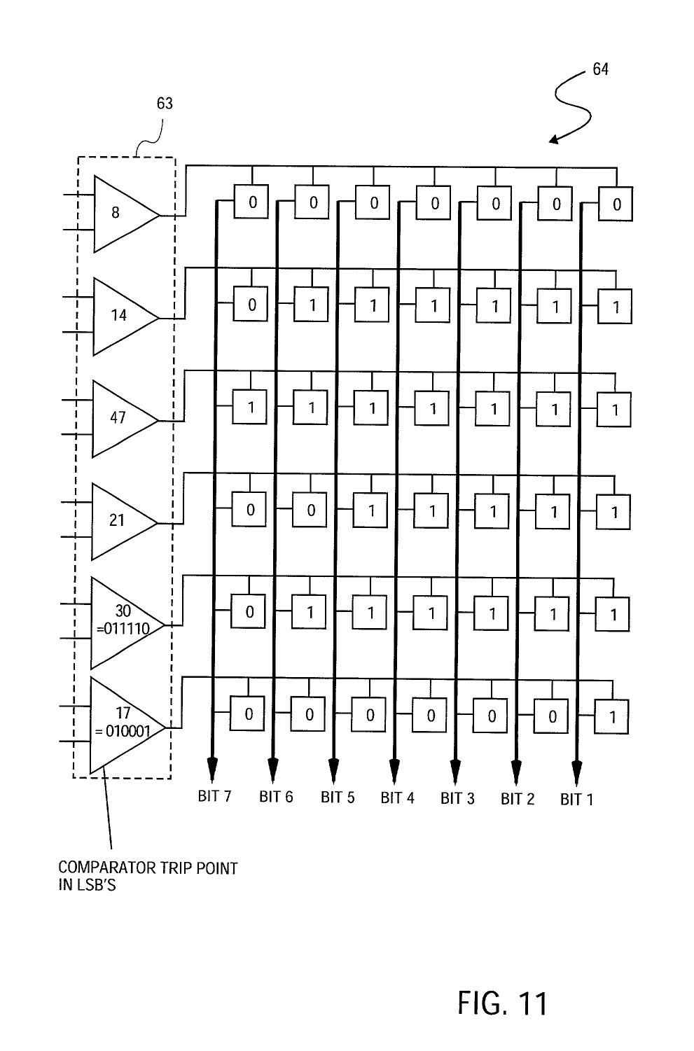

Further examples of words that may be written into rows corresponding to comparators are provided in FIG. 11.

Residues

Although FIG. 10, for the purposes of illustration, indicates the outputs of various comparators 63 accessing the memory cells of the SRAM 68, this is not physically the case in an exemplary embodiment. More specifically, it is the so-called “residue”, 75 in FIG. 7 and outputted from the MSB encoder 62, which provides input to the LSB encoder 64. In FIG. 11, the comparators 63 are merely included to illustrate a trip point (i.e., a comparator) to which an exemplary SRAM row belongs.

The “residue” 75 is derived from the outputs of the comparators 63, and is in fact a subset of the comparator outputs that are high. The residue 75 is formed by gating the outputs of the comparators 63 with segment information. For example, if the MSB encoder 62 indicates that the output lies in segment 1, the outputs of the comparators 63 in this segment are communicated to the LSB encoder 64 (i.e., ANDed with 1). The remaining comparator outputs are ANDed with 0, masking their values. In short, the comparator outputs that constitute the “residue” are compared to outputs from the segment of the input voltage range in which the actual input voltage lies.

Table 4, illustrated below, provides four examples of comparator outputs and resulting residues. The four examples correspond to four different input voltages A,B,C, and D to the ADC 50.

TABLE 4
Comparator outputs and corresponding residues

| Trip | | Comp | | Comp | | Comp | | Comp | |
|---|---|---|---|---|---|---|---|---|---|
| point/LSB | Comp # | O/P A | Res A | O/P B | Res B | O/P C | Res C | O/P D | Res D |
| 32 | 325 | 0 | 0 | 0 | 0 | 0 | 0 | 0 | 0 |
| | 249 | 0 | 0 | 0 | 0 | 0 | 0 | 0 | 0 |
| 30 | 157 | 0 | 0 | 0 | 0 | 0 | 0 | 0 | 0 |
| 29 | 233 | 0 | 0 | 0 | 0 | 0 | 0 | 0 | 0 |
| 28 | 12 | 0 | 0 | 0 | 0 | 0 | 0 | 0 | 0 |
| 27 | 330 | 0 | 0 | 0 | 0 | 0 | 0 | 1 | 1 |
| 26 | 211 | 0 | 0 | 0 | 0 | 0 | 0 | 1 | 1 |
| 25 | 273 | 0 | 0 | 0 | 0 | 0 | 0 | 1 | 1 |
| 24 | 80 | 0 | 0 | 0 | 0 | 0 | 0 | 1 | 1 |
| 23 | 72 | 0 | 0 | 0 | 0 | 0 | 0 | 1 | 0 |
| 22 | 69 | 0 | 0 | 0 | 0 | 0 | 0 | 1 | 0 |
| 21 | 47 | 0 | 0 | 0 | 0 | 1 | 1 | 1 | 0 |
| 20 | 311 | 0 | 0 | 0 | 0 | 1 | 1 | 1 | 0 |
| 19 | 222 | 0 | 0 | 0 | 0 | 1 | 1 | 1 | 0 |
| 18 | 137 | 0 | 0 | 0 | 0 | 1 | 1 | 1 | 0 |
| 17 | 301 | 0 | 0 | 0 | 0 | 1 | 1 | 1 | 0 |
| 16 | 313 | 0 | 0 | 0 | 0 | 1 | 1 | 1 | 0 |
| 15 | 110 | 0 | 0 | 0 | 0 | 1 | 0 | 1 | 0 |
| 14 | 164 | 0 | 0 | 0 | 0 | 1 | 0 | 1 | 0 |
| 13 | 49 | 0 | 0 | 0 | 0 | 1 | 0 | 1 | 0 |
| 12 | 32 | 0 | 0 | 0 | 0 | 1 | 0 | 1 | 0 |
| 11 | 56 | 0 | 0 | 1 | 1 | 1 | 0 | 1 | 0 |
| 10 | 120 | 0 | 0 | 1 | 1 | 1 | 0 | 1 | 0 |
| 9 | 142 | 0 | 0 | 1 | 1 | 1 | 0 | i | 0 |
| 8 | 179 | 0 | 0 | 1 | 1 | 1 | 0 | 1 | 0 |
| 7 | 247 | 0 | 0 | 1 | 0 | 1 | 0 | i | 0 |
| 6 | 321 | 1 | 1 | 1 | 0 | 1 | 0 | 1 | 0 |
| 5 | 145 | 1 | 1 | 1 | 0 | 1 | 0 | i | 0 |
| 4 | 4 | 1 | 1 | 1 | 0 | 1 | 0 | i | 0 |
| 3 | 234 | 1 | 1 | 1 | 0 | 1 | 0 | 1 | 0 |
| 2 | 61 | 1 | 1 | 1 | 0 | 1 | 0 | 1 | 0 |
| 1 | 29 | 1 | 1 | 1 | 0 | 1 | 0 | 1 | 0 |

It will be noted that Table 4 provides an example for a particular ADC 50 where the comparators 63 of that ADC 50 have a particular set of trip voltages. The first two columns of Table 4 list comparators that have been selected during calibration for trip points from 1 to 32*LSB.

Again considering the example of a 6-bit ADC, a total of 63 comparators may be assigned. In Table 4 only those corresponding to the lower 32 codes are shown for the purposes of illustration.

The remaining columns of Table 4 demonstrate how the residue 75 is derived in the case of four different values. Specifically, the “Comp O/P” columns each represent the comparator outputs and the “Res” columns represent the residue 75 for each of different input values A, B, C and D.

Dealing firstly with input voltage A, it will be noted from the comparator outputs in the “Comp O/P A” column that the input voltage is in segment 1. Thus the comparator outputs from segment 1 are passed to the residue 75.

For input voltage B, on examining the comparator outputs shown “Comp O/P B” it will be noted that the input voltage lies in segment 2. Thus the comparator outputs from segment 2 are passed to the residue 75.

For input voltage C, it will be noted from the comparator inputs in the column “Comp O/P C” that the input voltage is in segment 3. Accordingly, the comparator outputs from segment 3 are passed to the residue 75.

Similarly, for input voltage D, it will be noted that the input voltage is in segment 4, and the comparator outputs from segment 4 are accordingly passed to the residue 75.

As noted above, the residue 75 is a subset of the comparator outputs, in that a subset of the comparator outputs are passed by the MSB encoder 62 to form the residue 75. In one embodiment, this is achieved by performing an AND operation on an appropriate column of memory cells within the SRAM 66 of the MSB encoder 62 with comparator outputs.

For example, if input of voltage is in segment 3 of an input voltage range of the ADC (as in case C of Table 4), the residue 75 can be obtained by performing an AND operation utilizing row 2 of the SRAM 66 of the MSB encoder 62 with the comparator outputs. This is illustrated below in Table 5. For this example, 336 lines of a 6-bit ADC are passed to the LSB encoder 64, as also illustrated in FIG. 7. All but eight of the values are masked out, with the eight chosen values being dependent on which segment of the input voltage range the input voltage in fact lies within.

TABLE 5
Generation of Residue

| Trip | Comp | Comp | | MSB | MSB | MSB | MSB | SB | SB | MSB |
|---|---|---|---|---|---|---|---|---|---|---|
| point/LSB | # | O/P C | Res C | Row 1 | Row 2 | Row 3 | Row 4 | Row 5 | Row 6 | Row 7 |
| 32 | 325 | 0 | 0 | 0 | 0 | 0 | 1 | 0 | 0 | 0 |
| 31 | 249 | 0 | 0 | 0 | 0 | 1 | 0 | 0 | 0 | 0 |
| 30 | 157 | 0 | 0 | 0 | 0 | 1 | 0 | 0 | 0 | 0 |
| 29 | 233 | 0 | 0 | 0 | 0 | 1 | 0 | 0 | 0 | 0 |
| 28 | 12 | 0 | 0 | 0 | 0 | 1 | 0 | 0 | 0 | 0 |
| 27 | 330 | 0 | 0 | 0 | 0 | 1 | 0 | 0 | 0 | 0 |
| 26 | 211 | 0 | 0 | 0 | 0 | 1 | 0 | 0 | 0 | 0 |
| 25 | 273 | 0 | 0 | 0 | 0 | 1 | 0 | 0 | 0 | 0 |
| 24 | 80 | 0 | 0 | 0 | 0 | 1 | 0 | 0 | 0 | 0 |
| 23 | 72 | 0 | 0 | 0 | 1 | 0 | 0 | 0 | 0 | 0 |
| 22 | 69 | 0 | 0 | 0 | 1 | 0 | 0 | 0 | 0 | 0 |
| 21 | 47 | 1 | 1 | 0 | 1 | 0 | 0 | 0 | 0 | 0 |
| 20 | 311 | 1 | 1 | 0 | 1 | 0 | 0 | 0 | 0 | 0 |
| 19 | 222 | 1 | 1 | 0 | 1 | 0 | 0 | 0 | 0 | 0 |
| 18 | 137 | 1 | 1 | 0 | 1 | 0 | 0 | 0 | 0 | 0 |
| 17 | 301 | 1 | 1 | 0 | 1 | 0 | 0 | 0 | 0 | 0 |
| 16 | 313 | 1 | 1 | 0 | 1 | 0 | 0 | 0 | 0 | 0 |
| 15 | 110 | 1 | 0 | 1 | 0 | 0 | 0 | 0 | 0 | 0 |
| 14 | 164 | 1 | 0 | 1 | 0 | 0 | 0 | 0 | 0 | 0 |
| 13 | 49 | 1 | 0 | 1 | 0 | 0 | 0 | 0 | 0 | 0 |
| 12 | 32 | 1 | 0 | 1 | 0 | 0 | 0 | 0 | 0 | 0 |
| 11 | 56 | 1 | 0 | 1 | 0 | 0 | 0 | 0 | 0 | 0 |
| 10 | 120 | 1 | 0 | 1 | 0 | 0 | 0 | 0 | 0 | 0 |
| 9 | 142 | 1 | 0 | 1 | 0 | 0 | 0 | 0 | 0 | 0 |
| 8 | 179 | 1 | 0 | 1 | 0 | 0 | 0 | 0 | 0 | 0 |
| 7 | 247 | 1 | 0 | 0 | 0 | 0 | 0 | 0 | 0 | 0 |
| 6 | 321 | 1 | 0 | 0 | 0 | 0 | 0 | 0 | 0 | 0 |
| 5 | 145 | 1 | 0 | 0 | 0 | 0 | 0 | 0 | 0 | 0 |
| 4 | 4 | 1 | 0 | 0 | 0 | 0 | 0 | 0 | 0 | 0 |
| 3 | 234 | 1 | 0 | 0 | 0 | 0 | 0 | 0 | 0 | 0 |
| 2 | 61 | 1 | 0 | 0 | 0 | 0 | 0 | 0 | 0 | 0 |
| 1 | 29 | 1 | 0 | 0 | 0 | 0 | 0 | 0 | 0 | 0 |

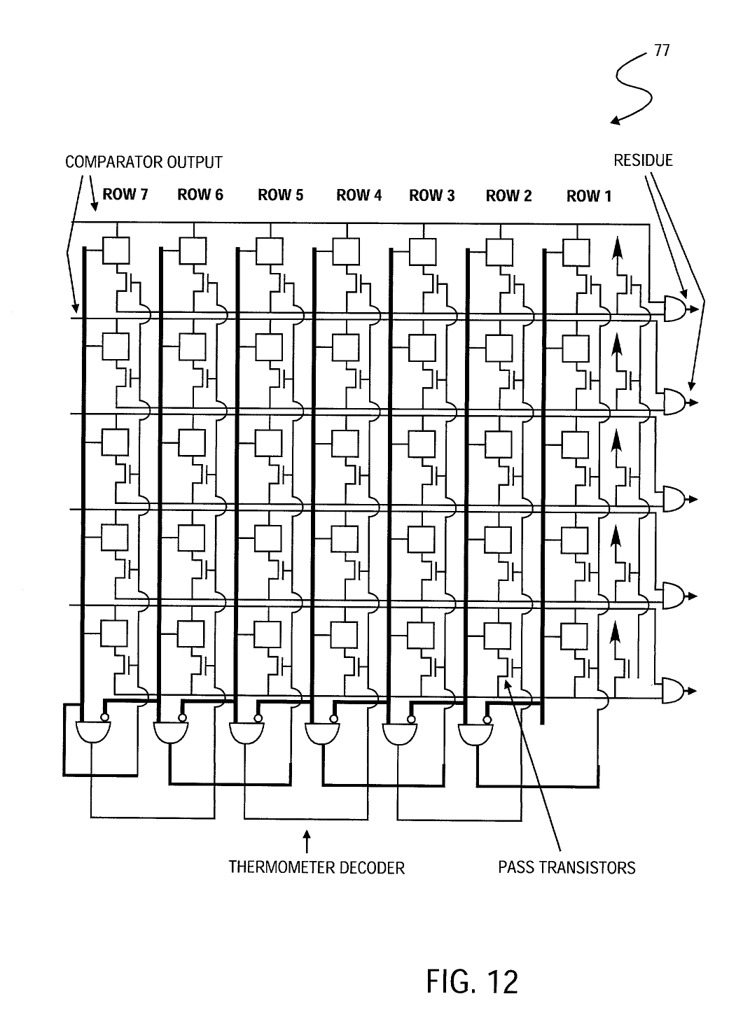

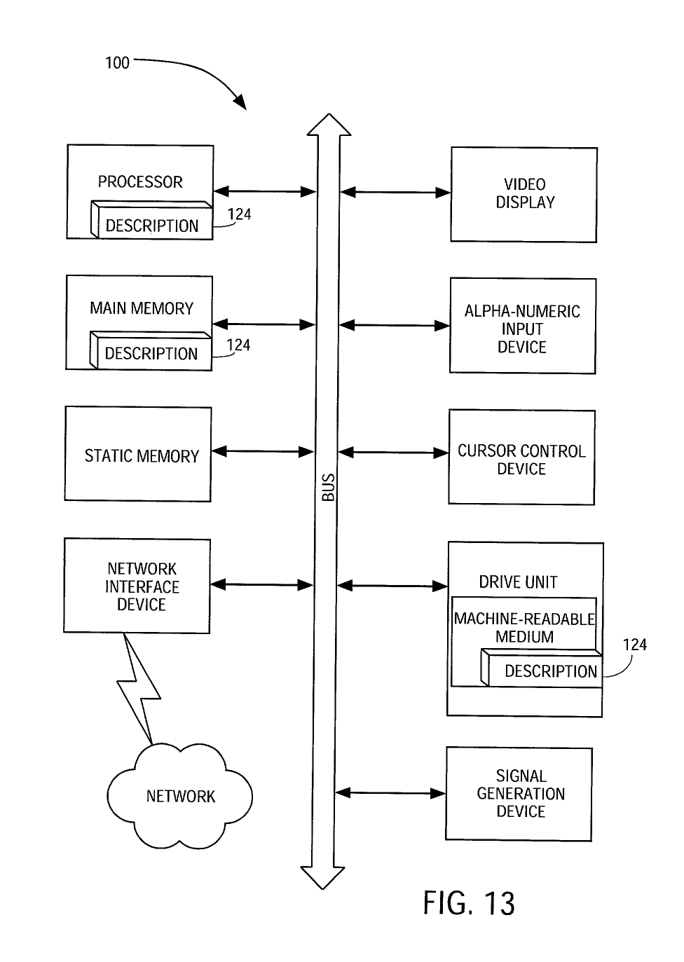

By determining which segment of the input voltage range is indicated by the comparator outputs, an appropriate row of the SRAM 66 of the MSB encoder 62 (e.g., from rows 1-7) may be ANDed with the comparator outputs to yield the residue 75. FIG. 12 is a schematic diagram illustrating a residue generator circuit 77, according to an exemplary embodiment of the present invention, which may be included within the MSB encoder 62 to generate and output the residue 75 to the LSB encoder 64. As can be seen in FIG. 12, a thermometer decoder identifies the segment of the input voltage range in which the input voltage lies. The output of the thermometer decoder passes the appropriate column to the input of AND gates. The AND gates then operate to AND the appropriate column with outputs of comparator 63, thereby to generate the residue 75.

While the present invention is described utilizing exemplary embodiments and use scenarios, it will be appreciated that the present invention may be utilized in any application where a pre-defined distribution of an analog quantity is required. For example, if an array of measurements at different delays is required, then a large number of delayed measuring blocks may be deployed. The most appropriate of these delayed measuring blocks may be chosen, and ordered if necessary, at calibration. The unused blocks may then be powered down.

Note also that embodiments of the present description may be implemented not only within a physical circuit (e.g., on semiconductor chip) but also within machine-readable media. For example, the circuits and designs discussed above may be stored upon and/or embedded within machine-readable media associated with a design tool used for designing semiconductor devices. Examples include a netlist formatted in the VHSIC Hardware Description Language (VHDL) language, Verilog language or SPICE language. Some netlist examples include: a behavioral level netlist, a register transfer level (RTL) netlist, a gate level netlist and a transistor level netlist. Machine-readable media also include media having layout information such as a GDS-II file. Furthermore, netlist files or other machine-readable media for semiconductor chip design may be used in a simulation environment to perform the methods of the teachings described above.

Thus, it is also to be understood that embodiments of this invention may be used as or to support a software program executed upon some form of processing core (such as the CPU of a computer) or otherwise implemented or realized upon or within a machine-readable medium. A machine-readable medium includes any mechanism for storing or transmitting information in a form readable by a machine (e.g., a computer). For example, a machine-readable medium includes read only memory (ROM); random access memory (RAM); magnetic disk storage media; optical storage media; flash memory devices; electrical, optical, acoustical or other form of propagated signals (e.g., carrier waves, infrared signals, digital signals, etc.); etc. FIG. 12 is a block diagram of a machine in the exemplary form of a computer system including a machine-readable medium on which a description of the present invention is stored.

Thus, a pruning calibration flash analog-to-digital converter (ADC) and a method of calibrating and manufacturing the same, have been described. Although the present invention has been described with reference to specific exemplary embodiments, it will be evident that various modifications and changes may be made to these embodiments without departing from the broader spirit and scope of the invention. Accordingly, the specification and drawings are to be regarded in an illustrative rather than a restrictive sense.

What is claimed:

1. A method to perform calibration of an ADC, the method including:
performing a pruning operation in relation to a plurality of comparators of the ADC to select a subset of selected comparators of the plurality of comparators as operational; and
disabling a subset of unselected comparators of the plurality of comparators.

2. The method of claim 1 wherein the ADC is a N-bit flash ADC, and the subset of selected comparators is selected to include 2ˆ N−1 comparators.

3. The method of claim 1 wherein the plurality of comparators includes at least four times a number of comparators minimally required to generate an N-bit output from the ADC.

4. The method of claim 1 wherein the subset of selected comparators includes less than a half of the plurality of comparators.

5. The method of claim 4 wherein the subset of selected comparators includes less than a quarter of the plurality of comparators.

6. The method of claim 1 wherein the plurality of comparators are wired into the ADC.

7. The method of claim 1 wherein the selection of the subset of selected comparators includes selecting a comparator of the plurality of comparators with a trip voltage appropriate to each code of an output of the ADC.

8. The method of claim 7 wherein the selecting of the comparator includes, for a respective code of the output of the ADC, identifying a code transition voltage for the respective code, identifying the comparator as the comparator of the plurality of comparators with a trip voltage nearest the code transition voltage for the respective code, assigning the identified comparator to a segment of an input voltage range of the ADC, and removing the identified comparator from further consideration for inclusion within the subset of selected comparators.

9. The method of claim 8 wherein the identifying of the code transition voltage for the respective code includes multiplying a bit number by a Least Significant Bit (LSB) of the respective code.

10. The method of claim 8 wherein the identifying of the comparator with the trip voltage nearest the code transition voltage for the respective code includes generating an analog input to the plurality of comparators for the respective code and sweeping the analog input around a region of the code transition voltage for the respective code to identifying the comparator.

11. The method of claim 10 wherein the analog input is generated as an output of a DAC.

12. The method of claim 11 wherein a calibration engine provides a digital input to the DAC to generate the analog input to the plurality of comparators.

13. The method of claim 1 wherein the disabling of the subset of unselected comparators includes powering down comparators included within the subset of unselected comparators.

14. The method of claim 1 wherein the disabling of the subset of unselected comparators includes configuring comparators included within the subset of unselected comparators to each have a logical output opposite to that of comparators included within the subset of selected comparators.

15. The method of claim 1 including constructing the ADC so that trip voltages of the plurality of comparators are distributed to extend past maximum and minimum voltages of an input voltage range of the ADC.

16. The method of claim 1 including constructing the ADC so that a trip point density of the plurality of comparators is greater over an input voltage range of the ADC than would be required for a nominal distribution.

17. The method of claim 1 including constructing the ADC so that a trip point density of the plurality of comparators is greater toward edges of an input voltage range of the ADC than would be required for a nominal distribution.

18. The method of claim 1 including constructing the ADC so that the plurality of comparators includes at least four times a number of comparators required to generate a N-bit output from the ADC.

19. The method of claim 1 wherein the selection of the subset of selected comparators is performed without regard for a physical order of the comparators of the subset of selected comparators, so that the subset of selected comparators is physically unordered with respect to a N-bit output of the ADC.

20. The method of claim 1 including configuring an encoder of the ADC to output a N-bit digital output based on inputs from the plurality of comparators in a manner that is not effected by the physical order of comparators of the subset of selected comparators within the ADC.

21. The method of claim 20 wherein encoder sums the output of the plurality of comparators to generate the N-bit digital output.

22. The method of claim 20 wherein the configuring of the encoder includes, for each output of the subset of selected comparators, programming a memory cell, corresponding to a bit corresponding to a segment of the input voltage range of the ADC, to reflect the segment of the input voltage range to which a respective comparator of the subset of selected comparators is assigned.

23. The method of claim 22 wherein the programming of the memory cell includes writing a Q-bit word to a row of memory cells within a memory of the encoder, the encoder including a row for each of the plurality of comparators.

24. The method of claim 23 wherein the Q-bit word, for each comparator of the subset of selected comparators, indicates a bit corresponding to a segment of an input voltage range of the ADC to which the respective comparator of the subset of selected comparators is assigned.

25. The method of claim 23 wherein the Q-bit word, for each comparator of the subset of unselected comparators, indicates that the respective comparator of the subset of unselected comparators is unassigned to a segment of the input voltage range of the ADC.

26. The method of claim 20 wherein the encoder outputs a N-bit binary code output corresponding to an analog input of the ADC.

27. The method of claim 26 wherein the encoder includes a Most Significant Bit (MSB) encoder to output m MSBs of the N-bit binary code output of the ADC and a Least Significant Bit (LSB) encoder to output the N-M LSBs of the binary code output of the ADC.

28. The method of claim 27 wherein the MSB encoder and the LSB encoder include first and second memories respectively each having a row of memory cells corresponding to each of the plurality of comparators, and the configuring of the encoder includes writing a respective Q-bit word to each of the rows of the first and second memories of both the MSB and LSB encoders corresponding to the subset of selected comparators to indicate a segment of the input voltage range of the ADC to which each of the comparators of the subset of selected comparators has been assigned.

29. The method of claim 28 wherein the LSB encoder is coupled to receive only the outputs of the subset of selected comparators from the MSB encoder.

30. The method of claim 28 wherein the first and second memories are coupled to respective first and second combinational logic, and wherein the first combinational logic receives a N-bit output from the first memory and generates a MSB binary output and the second combinational logic receives a N-bit output from the second memory and generates a LSB binary output.

31. An ADC circuit arrangement including:
a plurality of comparators, including redundant comparators; and
a calibration engine to perform a pruning operation in relation to the plurality of comparators of the ADC circuit arrangement to select a subset of selected comparators of the plurality of comparators as operational, and to operationally disable a subset of unselected comparators of the plurality of comparators.

32. The ADC circuit arrangement of claim 31 wherein the ADC circuit arrangement is a N-bit flash ADC, and the subset of selected comparators is selected to include 2ˆ N−1 comparators.

33. The ADC circuit arrangement of claim 31 wherein the plurality of comparators includes at least four times a number of comparators to generate an N-bit output from the ADC circuit arrangement.

34. The ADC circuit arrangement of claim 31 wherein the subset of selected comparators includes less than a half of the plurality of comparators.

35. The ADC circuit arrangement of claim 34 wherein the subset of selected comparators includes less than a quarter of the plurality of comparators.

36. The ADC circuit arrangement of claim 31 wherein the plurality of comparators are wired into the ADC.

37. The ADC circuit arrangement of claim 31 wherein the calibration engine, for each code of an output of the ADC circuit arrangement, selects each of the comparators of the subset of selected comparators with a trip voltage appropriate to the respective code of the output of the ADC.

38. The ADC circuit arrangement of claim 37 wherein the calibration engine, for each code of the output of the ADC circuit arrangement, identifies a code transition voltage for the respective code, identifies the comparator as the comparator of the plurality of comparators with a trip voltage nearest the code transition voltage for the respective code, assigns the identified comparator to a segment of an input voltage range of the ADC circuit arrangement, and removes the identified comparator from further consideration for inclusion within the subset of selected comparators.

39. The ADC circuit arrangement of claim 38 wherein the calibration engine identifies the code transition voltage for the respective code by multiplying a bit number by a Least Significant Bit (LSB) of the respective code.

40. The ADC circuit arrangement of claim 38 wherein the calibration engine identifies the comparator with the trip voltage nearest the code transition voltage for the respective code by generating an analog input to the plurality of comparators for the respective code and sweeping the analog input around a region of the code transition voltage for the respective code to identifying the comparator.

41. The ADC circuit arrangement of claim 40 including a DAC, and wherein the analog input is generated as an output of the DAC.

42. The ADC circuit arrangement of claim 41 wherein a calibration engine provides a digital input to the DAC to generate the analog input to the plurality of comparators.

43. The ADC circuit arrangement of claim 41 wherein the calibration engine powers down comparators included within the subset of unselected comparators.

44. The ADC circuit arrangement of claim 41 wherein the calibration engine configures comparators included within the subset of unselected comparators to each have a logical output opposite to that of comparators included within the subset of selected comparators.

45. The ADC circuit arrangement of claim 31 wherein trip voltages of the plurality of comparators are distributed to extend past maximum and minimum voltages of an input voltage range of the ADC circuit arrangement.

46. The ADC circuit arrangement of claim 31 wherein a trip point density of the plurality of comparators is greater over an input voltage range of the ADC circuit arrangement than would be required for a nominal distribution.

47. The ADC circuit arrangement of claim 31 wherein a trip point density of the plurality of comparators is greater toward edges of an input voltage range of the ADC circuit arrangement than would be required for a nominal distribution.

48. The ADC of claim 31 wherein the plurality of comparators includes at least four times a number of comparators required to generate a N-bit output from the ADC circuit arrangement.

49. The ADC circuit arrangement of claim 31 wherein the calibration engine performs selection of the subset of selected comparators without regard for a physical order of the comparators of the subset of selected comparators, so that the subset of selected comparators is physically unordered with respect to a N-bit output of the ADC circuit arrangement.

50. The ADC circuit arrangement of claim 31 including an encoder to output a N-bit digital output based on inputs from the plurality of comparators in a manner that is not effected by the physical order of comparators of the subset of selected comparators within the ADC circuit arrangement.

51. The ADC circuit arrangement of claim 50 wherein encoder sums the output of the plurality of comparators to generate the N-bit digital output.

52. The ADC circuit arrangement of claim 50 wherein the encoder includes, for each output of the subset of selected comparators, a programmed memory cell, corresponding to a bit corresponding to a segment of the input voltage range of the ADC circuit arrangement, to reflect the segment of the input voltage range to which a respective comparator of the subset of selected comparators is assigned.

53. The ADC circuit arrangement of claim 50 wherein the encoder outputs a N-bit binary code output corresponding to an analog input of the ADC circuit arrangement.

54. The ADC of claim 53 wherein the encoder includes a Most Significant Bit (MSB) encoder to output m MSBs of the N-bit binary code output of the ADC circuit arrangement and a Least Significant Bit (LSB) encoder to output the N-m LSBs of the binary code output of the ADC circuit arrangement.

55. The ADC circuit arrangement of claim 54 wherein the MSB encoder and the LSB encoder include first and second memories respectively each having a row of memory cells corresponding to each of the plurality of comparators, and configuring of the encoder includes writing a respective Q-bit word to each of the rows of the first and second memories of both the MSB and LSB encoders corresponding to the subset of selected comparators to indicate a segment of the input voltage range of the ADC circuit arrangement to which each of the comparators of the subset of selected comparators has been assigned.

56. The ADC circuit arrangement of claim 54 wherein the LSB encoder is coupled to receive only the outputs of the subset of selected comparators from the MSB encoder.

57. The ADC circuit arrangement of claim 55 wherein the first and second memories are coupled to respective first and second combinational logic, and wherein the first combinational logic receives a N-bit output from the first memory and generates a MSB binary output and the second combinational logic receives a N-bit output from the second memory and generates a LSB binary output.

58. An ADC circuit arrangement including:
comparator means, including redundant comparators; and
calibration means for performing a pruning operation in relation to a plurality of comparators of the ADC circuit arrangement to select a subset of selected comparators of the plurality of comparators as operational, and for operationally disabling a subset of unselected comparators of the plurality of comparators.

59. The ADC circuit arrangement of claim 58 wherein the calibration means, for each code of the output of the ADC circuit arrangement, is for identifying a code transition voltage for the respective code, for identifying the comparator as the comparator of the plurality of comparators with a trip voltage nearest the code transition voltage for the respective code, for assigning the identified comparator to a segment of an input voltage range of the ADC circuit arrangement, and for removing the identified comparator from further consideration for inclusion within the subset of selected comparators.

60. A machine-readable medium storing a description of an ADC circuit arrangement, said ADC circuit arrangement comprising:
a plurality of comparators, including redundant comparators; and
a calibration engine to perform a pruning operation in relation to a plurality of comparators of the ADC circuit arrangement to select a subset of selected comparators of the plurality of comparators as operational, and to operationally disable a subset of unselected comparators of the plurality of comparators.

61. The machine-readable medium of claim 60 wherein the description comprises a behavioral level description of the circuit.

62. The machine-readable medium of claim 61 wherein the behavioral level description is compatible with a VHDL format.

63. The machine-readable medium of claim 61 wherein the behavioral level description is compatible with a Verilog format.

64. The machine-readable medium of claim 60 wherein the description comprises a register transfer level (RTL) netlist.

65. The machine-readable medium of claim 60 wherein the description comprises a transistor level netlist.
